(19) United States
(12) Patent Application Publication
(10) Pub. No.: US 2024/0220249 A1
(43) Pub. Date: Jul. 4, 2024

(54) FLEXIBLE VECTORIZED PROCESSING ARCHITECTURE

(71) Applicant: Intel Corporation, Santa Clara, CA (US)

(72) Inventors: Jian-Guo Chen, Basking Ridge, NJ (US); David Dougherty, Allentown, PA (US); Madihally Narasimha, Saratoga, CA (US); Joseph Othmer, Ocean, NJ (US); Hong Wan, Allentown, PA (US); Joseph Williams, Holmdel, NJ (US); Zoran Zivkovic, Hertogenbosch (NL)

(21) Appl. No.: 18/147,099

(22) Filed: Dec. 28, 2022

(51) Int. Cl. G06F 9/30; G06F 30/343

(52) U.S. Cl. CPC G06F 9/30036; G06F 9/3001; G06F 30/343

(57) ABSTRACT

Techniques are disclosed for the implementation of a programmable processing array architecture that realizes vectorized processing operations for a variety of applications. Such vectorized processing operations may include digital front end (DFE) processing operations, which include finite impulse response (FIR) filter processing operations. The programmable processing array architecture provides a front-end interconnection network that generates specific data sliding time window patterns in accordance with the particular DFE processing operation to be executed. The architecture enables the processed data generated in accordance with these sliding time window patterns to be fed to a set of multipliers and adders to generate output data. The architecture supports a wide range of processing operations to be performed via a single programmable processing array platform by leveraging the programmable nature of the array and the use of instruction sets.

### TECHNICAL FIELD

The disclosure described herein generally relates to programmable processor array architectures and, in particular, to techniques for leveraging a programmable processing array architecture to accommodate a variety of different types of processing operations, such as supporting a range of different types of finite impulse response (FIR) digital filters.

### BACKGROUND

A programmable processing array, which may comprise a vector processor or an array processor, is a central processing unit (CPU) that implements an instruction set containing instructions that operate on one-dimensional arrays of data (i.e. sets of data samples) also referred to as “vectors.” This is in contrast to scalar processors having instructions that operate on single data items. Programmable processing arrays can greatly improve the performance on certain workloads, notably numerical simulation and similar tasks, by utilizing a number of execution units that independently execute specific functions on incoming data streams. However, current implementation of programmable processing arrays to achieve digital front end (DFE) processing operations have drawbacks.

### BRIEF DESCRIPTION OF THE DRAWINGS/FIGURES

The accompanying drawings, which are incorporated herein and form a part of the specification, illustrate the present disclosure and, together with the description, further serve to explain the principles and to enable a person skilled in the pertinent art to make and use the implementations as discussed herein.

FIG. 1 illustrates an example of a conventional vector processor architecture.

FIG. 2 illustrates another example of a conventional vector processor architecture.

FIG. 3 illustrates a programmable processing array architecture, in accordance with the disclosure.

FIG. 4A illustrates additional details of a programmable processing array architecture, in accordance with the disclosure.

FIG. 4B illustrates a conventional butterfly and inverse butterfly network.

FIG. 5 illustrates an output vector computation identified with filter processing operations in accordance with a half-band interpolation filter type, in accordance with the disclosure.

FIG. 6 illustrates an example device, in accordance with the disclosure.

FIG. 7 illustrates a process flow, in accordance with the disclosure.

The present disclosure will be described with reference to the accompanying drawings. The drawing in which an element first appears is typically indicated by the leftmost digit(s) in the corresponding reference number.

### DETAILED DESCRIPTION

In the following description, numerous specific details are set forth in order to provide a thorough understanding of the present disclosure. However, it will be apparent to those skilled in the art that the implementations of the disclosure, including structures, systems, and methods, may be practiced without these specific details. The description and representation herein are the common means used by those experienced or skilled in the art to most effectively convey the substance of their work to others skilled in the art. In other instances, well-known methods, procedures, components, and circuitry have not been described in detail to avoid unnecessarily obscuring the disclosure.

### Vector Processing Operation

Generally speaking, conventional CPUs manipulate one or two pieces of data at a time. For instance, conventional CPUs may receive an instruction that essentially says “add A to B and put the result in C,” with ‘C’ being an address in memory. Typically the data is rarely sent in raw form, and is instead “pointed to” via passing an address to a memory location that holds the actual data. Decoding this address and retrieving the data from that particular memory location takes some time, during which a conventional CPU sits idle waiting for the requested data to be retrieved. As CPU speeds have increased, this memory latency has historically become a large impediment to performance.

Thus, to reduce the amount of time consumed by these steps, most modern CPUs use a technique known as instruction pipelining in which the instructions sequentially pass through several sub-units. The first sub-unit reads and decodes the address, the next sub-unit “fetches” the values at those addresses, while the next sub-unit performs the actual mathematical operations. Vector processors, which are otherwise known as array processors, take this concept even further. For instance, instead of pipelining just the instructions, vector processors also pipeline the data itself. For example, a vector processor may be fed instructions that indicate not to merely add A to B, but to add all numbers within a specified range of address locations in memory to all of the numbers at another set of address locations in memory. Thus, instead of constantly decoding the instructions and fetching the data needed to complete each one, a vector processor may read a single instruction from memory. This initial instruction is defined in a manner such that the instruction itself indicates that the instruction will repeatedly be executed on another item of data, at an address one increment larger than the last. This allows for significant savings in decoding time.

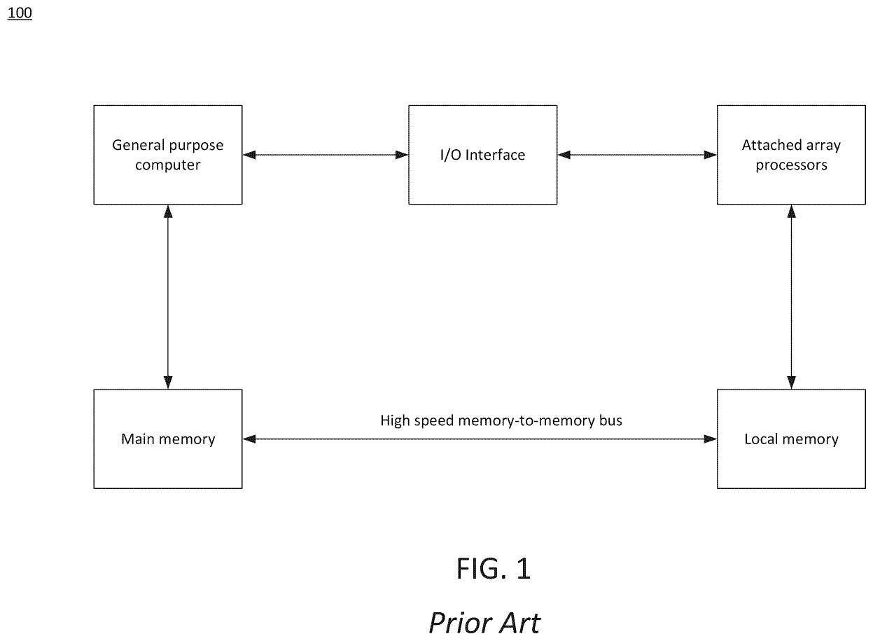

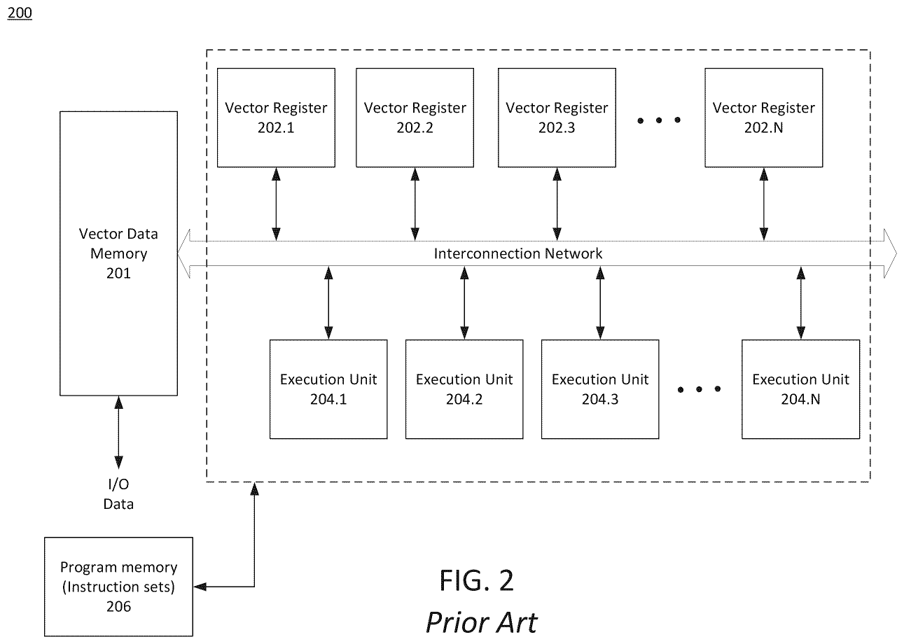

Vector processors may be implemented in accordance with various architectures, and the various vector processor architectures as discussed throughout the disclosure and further described herein may be implemented in accordance with any of these architectures or combinations of these architectures. FIGS. 1 and 2 provide two different implementations of a vector processor architecture. FIG. 1 illustrates an attached vector processor, which is attached to a general purpose computer, for instance, for the purpose of enhancing and improving the performance of that computer in numerical computational tasks. The attached vector processor achieves high performance by means of parallel processing with multiple functional units, which may be alternatively referred to herein as execution units or processing units.

FIG. 2, on the other hand, shows an example of a single instruction stream, multiple data streams (SIMD) vector processor. The vector processor architecture 200 as shown in FIG. 2 may have an architecture consisting of one or more execution units. Each execution unit is capable of executing one instruction. Each instruction can be a control, load/store, scalar or a vector instruction. Therefore, a processor with N execution units 204.1-204.N as shown in FIG. 2 can issue as many as N instructions every clock cycle. The execution units 204.1-204.N function under the control of a common control unit (such as processing circuitry), thus providing a single instruction stream to control each of the execution units 204.1-204.N. The I/O data as shown in FIG. 2 is typically identified with data communicated between the vector processor 200 and another data source or processor (which may be the common control unit or another processor) depending upon the particular application. The vector data memory 201 thus stores data received as input to be processed by the execution units 204.1-204.N, and data that is output or read from the vector data memory 201 after the data is processed. The vector processor architecture 200 as shown in FIG. 2 is an example of a load-store architecture used by vector processors, which is an instruction set architecture that divides instructions into two categories: memory access (loading and storing data between the vector data memory 201 and the vector registers 202.1-202.N) and the vector processing operations performed by the execution units 204.1-204.N using the data retrieved from and the results stored to the vector registers 202.1-202.N.

Thus, the load-store instruction architecture facilitates data stored in the vector data memory 201 that is to be processed to be loaded into the vector registers 202.1-202.N using load operations, transferred to the execution units 204.1-204.N, processed, written back to the vector registers 202.1-202.N, and then written back to the vector data memory 201 using store operations. The location (address) of the data and the type of processing operation to be performed by each execution unit 204.1-204.N is part of an instruction stored as part of the instruction set in the program memory 206. The movement of data between these various components may be scheduled in accordance with a decoder that accesses the instructions sets from the program memory, which is not shown in further detail in FIG. 2 for purposes of brevity. The interconnection network, which supports the transfer of data amongst the various components of the vector processor architecture 200 as shown in FIG. 2, is generally implemented as a collection of data buses and may be shared among a set of different components, ports, etc. In this way, several execution units 204.1-204.N may write to a single vector register 202, and the data loaded into several vector registers 202.1-202.N may be read by and processed by several of the execution units 204.1-204.N.

The use of instruction sets in accordance with the vector processor architecture 200 is generally known, and therefore an additional description of this operation is not provided for purposes of brevity. Regardless of the particular implementation, vector processors can greatly improve performance on certain workloads but have various drawbacks. For instance, it is very common in many signal processing applications for a specific vector to be used many times in the calculation of an expression. In one scenario, for the implementation of a finite impulse response (FIR) filter, each vector data sample is multiplied by every coefficient of the filter. Thus, if a filter has 127 coefficients, then each vector data sample will be used as the input to 127 multiply-accumulate operations. This property is referred to as “data reuse.” In conventional vector processors, such as the vector processor architecture 200 as shown in FIG. 2, data reuse is achieved by storing the data in the vector registers 202.1-202.N, which has several drawbacks.

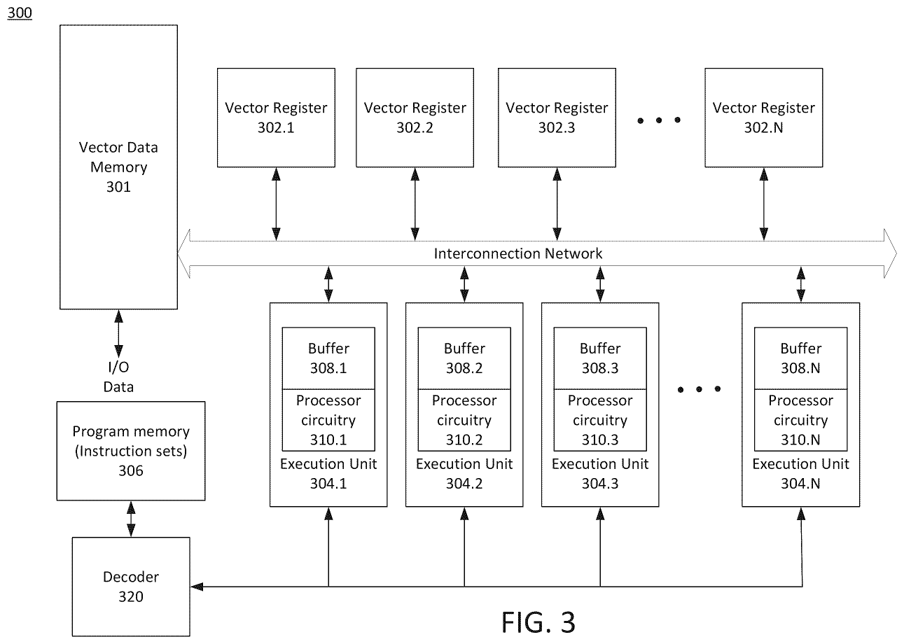

One drawback of this scheme is that, to enable practical compiler design, the vector registers 202.1-202.N must be implemented with aligned access. For such an approach, the vector data must reside entirely within the same entry of each element in the vector register file. However, it is common in many algorithms for the data to span across 2 or more entries of a register file, which is referred to as unaligned access. Conventional vector processors, such as the vector processor architecture 200 as shown in FIG. 2, perform unaligned access by reading two vectors of data from the register files although there is only one vector of useful data, which is inefficient in terms of both cost and power. Another drawback is that conventional processor architectures do not exploit the properties of streaming data applications, which is discussed in further detail herein with respect to the programmable processing array architecture 300 as shown in FIG. 3.

Moreover, signal processing for wireless systems, particularly newer standards such as the 3rd Generation Partnership Project (3GPP) Release 16 5G Phase 2 specification, the most recent at the time of this writing, require a high throughput at low power levels beyond what is possible in a conventional programmable vector/VLIW DSP architectures such as those illustrated in FIGS. 1 and 2. Further complicating this issue, there is often a need for digital front end (DFE) processing operations, such as filter processing operations, which may vary with respect to the type of filter that is required and/or the implementation of the filter within the RF chain.

The disclosure as further described herein addresses these issues by optionally implementing a local buffer as part of each execution unit in conjunction with an architecture that implements unicast inverse butterfly networks, multicast butterfly networks, and multiplication and adder units. This architecture provides for an efficient means by which to implement a wide range of DFE processing operations on a single unified programmable processing array platform. This also reduces the computational energy required to process sets of data samples, which may be particularly beneficial for wireless communication data processing.

### Programmable Processing Array Architecture

FIG. 3 illustrates a programmable processing array architecture in accordance with the disclosure. The programmable processing array architecture as shown in FIG. 3 may be implemented as a vector processor or other suitable type of array processor, and may be configured in accordance with any suitable type of array processor application and implementation, which may utilize any suitable type of processor, CPU, etc. This may include standard, reduced instruction set computer (RISC), such as super scalar, very long instruction word (VLIW), graphics processing units (GPUs), etc. As noted above with reference to the vector processor architecture 200 as shown in FIG. 2, the programmable processing array architecture 300 as shown in FIG. 3 may also include any suitable number N of vector registers 302.1-302.N and execution units 304.1-304.N. The load-store machine architecture facilitates the programmable processing array architecture 300 moving data between the vector data memory 301, the vector registers 302.1-302.N, and the execution units 304.1-304.N. The vector registers 302.1-302.N may alternatively be referred to as vector register files, and may represent any suitable type of storage such as volatile or non-volatile memory, and which may have any suitable size, addressable space, and address configuration depending upon the size of the data samples that are loaded into the vector registers 302.1-302.N, which may be stored as data vectors in one or more vector register files, which is typically a function of the particular instruction set and/or protocol such as vector size, word size, etc.

Again, the programmable processing array architecture 300 may be implemented as part of or work in conjunction with a specialized component such as a digital signal processor (DSP) and/or a radio transceiver that implements digital signal processing to perform various operations that may be utilized as part of wireless signal processing applications associated with wireless data communications. Thus, and with respect to the vector processing operations (also referred to herein simply as processing operations), these operations may be any suitable type of function that operates on the sets of data samples (such as vectors) stored in each execution unit 304's respective local buffer 308.1-308.N, which is retrieved by each respective execution unit 304 from one or more of the vector registers 302.1-302.N in accordance with one or more received vector processor instructions. Again, such vector processing operations may include digital signal processing operations that are associated with wireless data communications.

The functions may be implemented as part of the particular application in which the programmable processing array architecture 300 is utilized, which may be digital front end (DFE) processing operations and/or digital signal processing (DSP) operations for wireless communications. These may include the application and/or calculation of finite impulse response (FIR) filter contributions to a digital data stream, equalizer functions, the calculation of digital pre-distortion (DPD) coefficients or terms, the application or calculation of Fast Fourier Transforms (FFTs) and/or discrete Fourier Transforms (DFTs), matrix operations, mixer and/or frequency correction calculations, peak detection and/or cancellation calculations, signal measurements, average signal measurement calculations over time, digital signal processing of signals transmitted or received via individual antenna data streams for multiple-input-multiple-output (MIMO) antenna systems, etc. Furthermore, the sets of data samples as discussed herein (which may alternatively be referred to as vectors, data vectors, or data vector samples when implemented as part of a vector processor architecture) may be part of an in-phase (I) quadrature-phase (Q) data stream, which may be processed prior to data transmission of wireless signals or after receiving the wireless signals. Additionally or alternatively, such functions may be implemented as part of graphics processing unit (GPU) to perform graphics processing and/or rendering.

The programmable processing array architecture 300 may also include any suitable number of execution units 304.1-304.N, which may implement any suitable type of array processors, such as vector processors, vector processing circuitry, etc., illustrated in FIG. 3 as the processor circuitry 310.1-310.N, and which may be implemented to perform specific types of data processing operations based upon respectively received commands or instructions. These commands or instructions may originate from a decoder or other suitable processor that functions to arbitrate or otherwise schedule the processing of I/O data that is stored in the vector data memory 301 and transferred from the vector data memory 301 to the vector registers 302.1-302.N using the interconnection network. The execution units 304.1-304.N may alternatively be referred to herein as vector units, vector processing units, or functional units, or further alternatively as execution unit circuitry, vector unit circuitry, vector processing unit circuitry, functional unit circuitry, or simply as one or more processors. The execution units 304.1-304.N may be implemented in accordance with any suitable type of programmable processing array architecture and include any suitable number and/or type of array processing circuitry, as shown in FIG. 3 as the processor circuitry 310.1-310.N, and which may include known programmable processing array and/or vector processor architectures and/or types, to perform their respective processing operations.

Each of the execution units 304.1-304.N is configured to perform a specific type of mathematical operation via bit manipulation such as multiplication, addition, etc. Each of the execution units 304.1-304.N includes respective processor circuitry 310.1-310.N and is configured to execute, for each clock cycle, a set of specific types of processor instructions in accordance with one or more processor instructions, which may be received as a fused processor instruction or as several individual processor instructions received over several respective clock cycles. Thus, the programmable processing array architecture 300 may receive individual processor instructions over several clock cycles, performing a single processor instruction per clock cycle or, alternatively, receive a fused or concatenated vector processor instruction that includes any suitable number of vector processor instructions to be computed over one or more suitable number of clock cycles. The set of processor instructions that are fused into a single vector processor instruction, which is received by one or more of the execution units 304.1-304.N per clock cycle, may be encoded as various fields, each respecting a particular vector processor operation that is to be performed.

In any event, the execution units 304.1-304.N are configured to independently execute any suitable number of processor instructions each clock cycle in parallel with one another, as defined by each respectively received processor instruction (which again may contain any suitable number of encoded processing instructions for respective processing operations). Because these instructions may be different than one another, the use of multiple execution units 304.1-304.N means that the programmable processing array architecture 300 may execute N number of instructions in parallel each clock cycle. Thus, the programmable processing array architecture 300 as described herein may utilize a data format of processor instructions such that each processor instruction enables flexibility for the execution units 304.1-304.N to perform any suitable number and type of processor operations in accordance with a wide range of algorithms and applications.

The programmable processing array architecture 300 may form part of or the entirety of a system on a chip (SoC), which may be part of a larger overall system in which the programmable processing array architecture 300 is implemented. That is, the programmable processing array architecture 300 may be instantiated as part of a broader SoC that may include several other processors, ports, RF chains, I/O, etc. In such a scenario, the I/O data coupled to the vector data memory 301 as shown in FIG. 3 may represent a SoC bus, which functions to write data to the vector data memory 301 and to read data from the vector data memory 301. The communications between the vector data memory 301 and another entity using the SoC bus may be via Direct Memory access (DMA) or other suitable means. Thus, and as noted above for the vector processor architecture 200, the interconnection network may be a shared resource, and reducing the data transferred over the interconnection network thus reduces computational latency and power usage requirements.

Therefore, in contrast to the vector processor architecture 200 as shown in FIG. 3, each of the execution units 304.1-304.N as shown in FIG. 3 includes a buffer 308.1-308.N, which may be implemented as any suitable type of memory having suitable size, addressable space, and address configuration. Each of the execution units 304.1-304.N also includes respective processor circuitry 310.1-310.N, which performs the aforementioned instructions and thus constitutes the portion of the execution units 304.1-304.N that interfaces with the streaming buffers 308.1-308.N, performs the requested processing operations each clock cycle, and then writes the result back to either a respective buffer 308.1-308.N (if more vector processing operations are to be performed locally by the execution unknit 304) or to the one or more of the vector registers 302.1-302.N (once the execution unit 304 has completed the necessary vector processing operations) as discussed in further detail below.

The buffers 308.1-308.N may be implemented as memory of a size smaller than each of the vector registers 302.1-302.N, which may include a size just large enough to hold sets of data samples until the data samples are fully processed. The connections between the buffers 308.1-308.N and each respective processor circuitry 310.1-310.N are not shown in detail in FIG. 3 for purposes of brevity. However, because each buffer 308.1-308.N is local with respect to each execution unit 304.1-304.N, the data bandwidth between each buffer 308.1-308.N and its respective processor circuitry 310.1-310.N may be increased beyond the data bandwidth that would be available using the interconnection network, which represents an arbitrated and complex combination of shared data lanes.

The programmable processing array architecture 300 as described herein may be implemented in accordance with any suitable type of application that utilizes processing operations in accordance with any suitable type of processor instruction set (such as vector processing operations/instructions), and which may include individual and/or fused vector processor instruction(s). The processor instructions may be generated by any suitable controller, processor component, etc., such as the decoder 320 as shown in FIG. 3. When a fused processor instruction is used, it may include any suitable number of fields to facilitate the execution of various processor operations. A fused processor instruction may include fields representing various types of commands, pointers to address locations in the buffers 308.1-308.N (or the data vector memory 301) from which the processing circuitry 310.1-310.N is to read and write data, the particular type of mathematical function or processing operation that should be performed by a respective execution unit 304 to which the instruction is sent, etc. The use of fused processor instructions in this manner is known, and thus additional details regarding the use of the fused processor instructions in this manner are not provided for purposes of brevity. In any event, each execution unit 304.1-304.N is configured to execute any suitable number of processing operations per each received vector processor instruction, which may be sent to the execution units 304.1-304.N by the decoder 320 each clock cycle in accordance with a common system clock.

It is noted that for streaming applications the data is processed in a sequential order. Thus, a natural memory structure for streaming data is a circular buffer. The buffers 308.1-308.N may thus be implemented as circular buffers and be configured such that data is written into the end of the circular buffer and read from the beginning of the circular buffer in terms of the buffer's addressable space. Another advantage of using such a circular buffer configuration includes the ability to utilize simplified modulo addressing to read data from and write data to the circular buffer. As it is not practical for compilers to support circular addressing for the vector registers 302.1-302.N, the use of the local buffers 308.1-308.N, which may locally implement such circular addressing, is particularly advantageous and overcomes this issue. The buffers 308.1-308.N may each be further partitioned into any suitable number of additional buffers or “sub-buffers,” which may be referred to herein as virtual buffers or buffer partitions, or simply as buffers with the understanding that the smaller buffer partitions may form part of a larger buffer component.

Moreover, in many streaming applications such as FIR filters, mixers, and DPD actuators used in Digital Front-Ends (DFEs), the processing may be formulated as a single instruction that is repeatedly executed in a single execution unit 304.1-304.N. Again, transferring data to and from the vector registers 302.1-302.N over the shared interconnection network is expensive in terms of both cost and power due to the complex architecture of interconnection networks and their typical implementation to support “many-to-many” communication features in accordance with vector processor architecture and design. The programmable processing array architecture 300 described herein may leverage the use of the buffers 308.1-308.N by exploiting the sequential nature of processing operations for certain applications, such as filter processor operations, that utilize streaming data. As discussed herein, the use of the buffers 308.1-308.N as part of the programmable processing array architecture 300 exploits the sequential and predictive nature of the computations performed for certain applications to eliminate the need for costly and complex data caches.

### A Programmable Processing Array Architecture for DFE Processing Operations

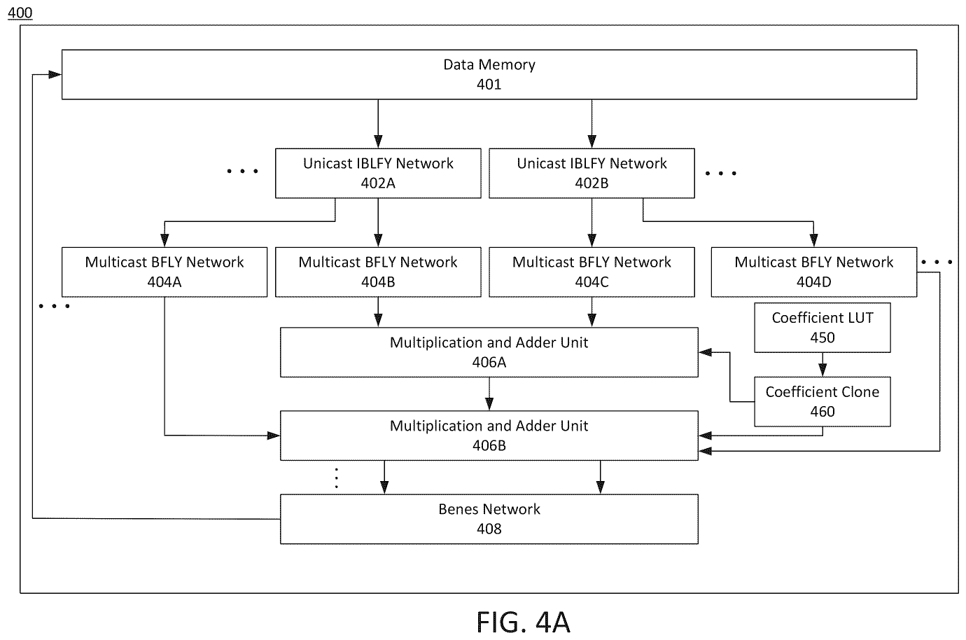

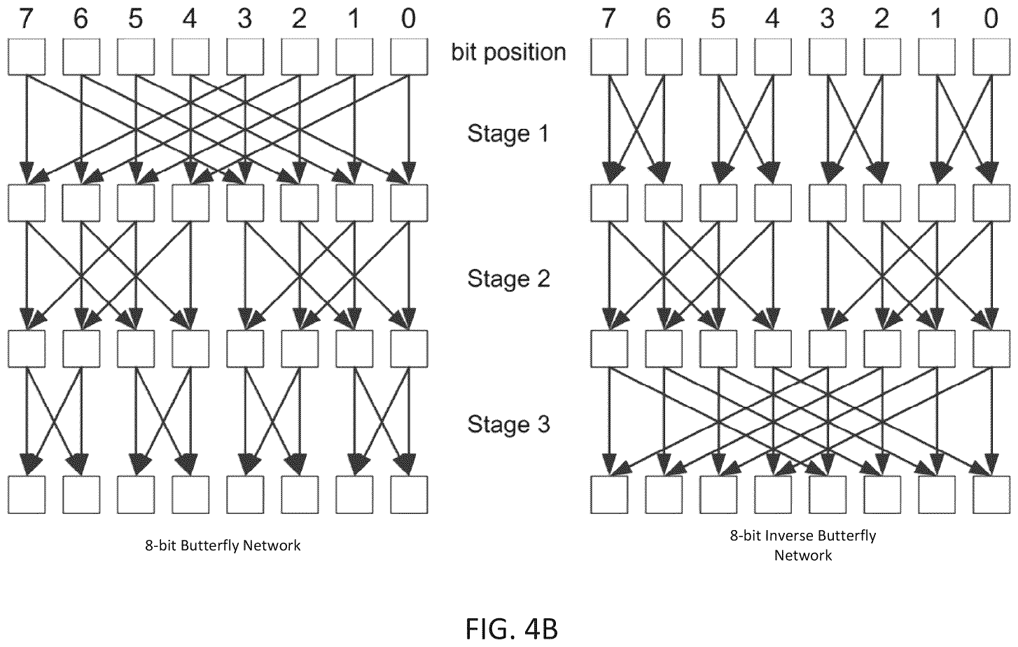

FIG. 4A illustrates additional details of a programmable processing array architecture, in accordance with the disclosure. The programmable processing array architecture 400 (also referred to herein as a programmable processing array 400) as shown in FIG. 4A may be implemented in accordance with any suitable type of processor architecture, such as a vector processor architecture or any other suitable type of array processor architecture that is configured to execute processing operations on sets of data samples (such as vectors) in accordance with received instructions that comprise part of an instruction set, as discussed above. In accordance with a non-limiting and illustrative scenario, the programmable processing array architecture 400 as shown in FIG. 4A may be identified with the programmable processing array architecture 300 as shown in FIG. 3, with FIG. 4A identifying additional details regarding the configuration and processing operations implemented to realize any suitable type of processing operations on data samples retrieved from the data memory 401. Thus, as was the case for the programmable processing array 300, the programmable processing array 400 may likewise form part of or the entirety of a system on a chip (SoC), which may be part of a larger overall system in which the programmable processing array architecture 400 is implemented.

Thus, the data memory 401 may be identified with any suitable type of memory and/or buffer that is configured to store sets of data samples of any suitable format and/or data samples stored in accordance with any suitable type of addressable configuration. Each set of data samples may comprise any suitable number of data samples (also referred to herein as elements or data elements) depending upon the particular application and/or implementation of the programmable processing array 400. In an non-limiting and illustrative scenario in which the programmable processing array 400 is identified with a vector processor architecture, the data memory 401 may be identified with the vector data memory 301, and store sets of data samples that comprise vectors (also referred to herein as data vectors).

Thus, each set of data samples, or data vectors in such a case, may comprise any suitable number of data samples such as 16, 32, 64, etc. In this way, and as further discussed below, the various functional blocks of the programmable processing array 400 may perform processing operations on one or more data vectors to perform processing operations on each of the data samples contained therein, thereby generating processed data vectors that comprise processed data samples having undergone any suitable number and/or type of processing operation in accordance with the received instruction(s), as noted above. As further discussed below, once the various processing operations have been completed on the data samples retrieved from the data memory 401, the output data vector, which comprises each of the processed data samples, are written back to the data memory 401. In this way, the platform in which the programmable processing array 400 forms a part may implement a data flow by accessing the sets of data samples stored in the data memory 401 at various times based upon the particular application and processing operations that are performed.

Again, the disclosure describes the processing operations executed via the programmable processing array 400 as various DFE processing operations performed in accordance with a selected DFE function, and in particular focuses on the implementation of various FIR filter processing operations. However, it is noted that the programmable processing array 400 is not limited to the use of FIR filter processing operations or DFE processing operations, and may be implemented in accordance with any suitable type of application that utilizes vector (or data set) addition and multiplication to realize any suitable type of array processing on retrieved data samples.

To this end, it is noted that the architecture of the programmable processing array 400 may be particularly useful for implementing FIR processing operations. That is, there are various ways of implementing vectorized FIR filters, although each of these techniques implements a front-end interconnection network to generate specific data sliding time window patterns to feed fixed computational units, which comprise adders and multipliers, as well as a post-processing formatting network to compact the output of the computational unit into natural format. For instance, most conventional techniques for implementing FIR processing operations either use full crossbar switches or a cascade of fixed-wiring harnesses and a bank of multiplexers to realize the front-end interconnection and post processing formatting networks. Crossbar switches are costly to implement in silicon, as such components have N² complexity, where N denotes the number of vector data lanes. Moreover, fixed-wiring harnesses lack the flexibility to include additional filter types as a design evolves. Furthermore, a DFE function for a conventional wireless device such as a base station requires various FIR filter types including interpolators, decimators, and fractional rate converters, which are individually implemented, thereby increasing the cost and complexity of such designs.

To address this issue, the architecture of the programmable processing array 400 enables filter processing operations to be performed on data samples read from the data memory 401 in accordance with a “superset” of any suitable number of different selectable filter types. The filter processing operations may thus be implemented efficiently via the programmable processing array 400 in accordance with any suitable number of these different FIR filter types by exploiting the symmetry and sparsity of the filter coefficients.

To do so, the programmable processing array 400 may implement functional blocks having a predetermined wired arrangement with respect to the data memory 401 and other functional blocks from which data samples are received from and transmitted to. Although these functional blocks may have a predetermined hardwired configuration to support data flows in accordance with a predetermined data sample size and data “lanes,” the actual processing operations performed by each of the functional blocks on sets of data samples is not fixed, but may be dynamically adjusted in accordance with the instructions that are received via the execution units 304.1-304.N. As further discussed herein, these processing operations may represent a time-shift, bit manipulation, or any other suitable function such as mathematical functions. Such processing operations are executed on received sets of data samples to generate processed data samples (or output data samples) that are transmitted to the next functional block or stage within the data flow implemented by the programmable processing array 400 in accordance with the processor instructions. Thus, the term processing operation or filter processing operation as used herein may encompass any suitable type of operations that result in the generation of output data via each of the functional blocks of the programmable processing array 400. These processing operations may thus include de-rotation, time-shifting to generate the sets of data samples in accordance with a time-sliding window pattern, multiplication and summation, interleaving, etc.

In other words, the programmable processing array 400 is configured to realize a set of any suitable number and/or type of processing operations, such as those identified with DFE functions as discussed herein. The architecture advantageously implements two vector multipliers and pre-adders in a data pipeline configuration to provide an efficient solution across various processing tasks, although the number of pre-adders and multipliers is shown as a non-limiting and illustrative scenario, and additional units may be implemented. As further discussed below, the programmable processing array 400 implements an interconnection network that generates the various data sliding time window patterns to efficiently cover a large set of filter types, as well as an output interface that functions as a post-processing formatting network (such as a Benes network) to perform the output data compaction. This architecture is in contrast to conventional front-end interconnection and post processing formatting networks as noted above, as the complexity of the networks used in accordance with the programmable processing array 400 architecture is N*log(N) as opposed to N² for crossbar fabrics. In addition, the configuration of the programmable processing array 400 allows for the flexibility to include additional filter types as the design evolves by changing the control bits of the switching fabrics, which may be realized in accordance with the processor instructions that are used.

The various functional blocks in addition to the data memory 401 as shown in FIG. 4A may comprise part of a programmable processing array architecture, and thus be referred to herein as part of a programmable processing array or as part of vector processing circuitry. In any event, each of the functional blocks as shown in FIG. 4A in addition to the data memory 401 may be implemented via the execution units 304.1-304.N and interconnection network as shown and discussed above with respect to the programmable processing array 300. In this way, and as further discussed below, each of the functional blocks in addition to the data memory 401 as shown in FIG. 4A may function as a processing operation pipeline, and provide a sequential series of processing operations that may be executed by one or more of the execution units 304.1-304.N as discussed herein with reference to FIG. 3. Thus, the various functional blocks in addition to the data memory 401 as shown in FIG. 4A may be implemented via the execution units 304.1-304.N, which respectively execute the processing operations on received data samples via the processor circuitry 310.1-310.N. It is noted that the number and arrangement of the functional blocks as shown in FIG. 4A is a non-limiting and illustrative scenario, and the programmable processing array 400 may include additional, fewer, or alternate arrangement of such functional blocks.

The programmable processing array 400 may utilize individual instructions per processing operation, or alternatively utilize fused or concatenated vector processing instructions, which may be a single vector processor instruction having a number of fields that represent or otherwise encode individual vector processing instructions. In other words, for a single fused vector processor instruction, an execution unit 310.1-310.N may (via the vector processor circuitry 304.1-304.N) perform any suitable number of processing operations in accordance with each of the individual processor instructions indicated by the fields contained within the fused processor instruction. In any event, the individual and/or the fused processor instruction(s) may include any suitable type of machine-readable code, opcode, etc. that may be read by the execution units 304.1-304.N and/or the processor circuitry 310.1-310.N implemented by each of the execution units 304.1-304.N.

Furthermore, the individual and/or fused processor instructions may represent encoded processor instructions, and thus identify respective processing instructions. Such instructions may indicate a number of computations to perform, a number and location (such as a read pointer address location) from which to retrieve data samples from the data memory 401, a number of data samples to retrieve from the data memory 401, a location from which the vector data samples are stored or written to the data memory 401 (such as write pointer address starting locations), a location (such as a read pointer starting address location) of an address of the buffers 308.1-308.N to read the vector data samples, a number and/or type of vector processing operations to perform on vector data samples read from the buffers 308.1-308.N, a location (such as a write pointer starting address location) in the buffers 308.1-308.N to write the results of performing the vector processing operations, etc.

The various functional blocks as shown in FIG. 4A and further discussed herein may alternatively be implemented as dedicated hardware, software, or any suitable combination thereof, each being configured to execute one or more specific types of processing operations in accordance with the received processor instructions. This may include dedicated hardware configurations of known types to perform specific types of mathematical functions or other suitable processing operations, and may include (when implemented using the execution units 304.1-304.N) one or more predetermined functions that the execution units 304.1-304.N are configured to execute upon receiving processor instruction(s). Again, the illustrated architecture as shown in FIG. 4A is provided for ease of explanation and not by limitation, and may include any suitable number and/or type of functional blocks depending upon the particular application, sampling rate, and/or the required number and/or type of processing operations that need to be executed for a particular application.

Thus, and with continued reference to FIG. 4, the programmable processing array 400 may comprise any suitable number of unicast inverse butterfly networks, with two being shown in FIG. 4A as 402A, 402B. A unicast inverse butterfly network (IBFLY) is a specific implementation of a butterfly network, which is a form of a multistage interconnection network topology used to connect different nodes in a multiprocessor system. For purposes of clarity, FIG. 4B illustrates the structure of an 8-bit butterfly network on the left, and an 8-bit inverse butterfly network on the right. Although the butterfly and inverse butterfly networks as shown in FIG. 4B comprise 8 bits each, this is for ease of explanation, and may comprise any suitable configuration of n-bit circuits by expanding upon the architecture as shown. The unicast IBFLY networks 402A, 402B may implement such a circuit structure as the 8-bit inverse butterfly network on the right, with the number of bits being modified to accommodate the size of the data sample sets upon which the unicast IBFLY networks 402A, 402B operate (such as 32 bits).

Thus, and with reference to FIG. 4B, each n-bit circuit may consist of log(n) stages, with each stage comprising n/2 2-input switches. Furthermore, each switch is comprised of two 2:1 multiplexers, totaling n×log(n) multiplexers for each circuit, leading to small overall circuit area. In the ith stage (i starting from 1), the paired bits are n/2i positions apart for the butterfly network and 2i−1 positions apart for the inverse butterfly network. A switch either passes through or swaps its inputs based on the value of a control bit, which may be provided by way of the processor instructions as noted herein. Thus, the operation requires n/2×log(n) control bits.

The unicast IBFLY networks 402A, 402B are each coupled to the data memory 401 via repetitive sets of wired interconnections, which may represent data lanes of any suitable width in terms of data sample size. The interconnections between the data memory 401 and the unicast IBFLY networks 402A, 402B may thus represent a set of predetermined wired interconnections that enable loading of sets of data samples (such as vectors) of a predetermined size from the data memory 401.

However, it is noted that the data stored in the data memory 401 may not be time-aligned in terms of the order of the data samples that are to be processed. In other words, the data samples may be stored in the data memory 401 in a “rotated,” or unaligned manner, which need to be de-rotated (i.e. time aligned) prior to the processing operations being performed. Thus, the unicast IBFLY networks 402A, 402B are configured to “de-rotate” (when necessary) each set of data samples (such as vectors) with respect to the data lanes utilized by the multicast butterfly networks 404A, 404B, 404C, and 404D, as further discussed below. In other words, each unicast IBFLY network 402A, 402B is configured to output, to each respectively coupled multicast butterfly network 404A, 404B, 404C, and 404D, sets of data samples (such as vectors) comprising time-aligned data samples. Thus, the interconnections between the unicast IBFLY networks 402A, 402B and each respectively-coupled multicast butterfly network 404A, 404B, 404C, 404D may represent a set of predetermined wired interconnections that enable loading of sets of time-aligned data samples (such as vectors) of a predetermined size from each of the unicast IBFLY networks 402A, 402B to each multicast butterfly network 404A, 404B, 404C, 404D as part of a respective data lane.

The unicast IBFLY network 402A outputs the same data to each of the multicast butterfly networks 404A, 404B, which again may represent time-aligned data samples after de-rotation of the data samples retrieved form the data memory 401. The unicast IBFLY network 402B also outputs the same data to each of the multicast butterfly networks 404C, 404D, which may also represent time-aligned data samples. However, the data output by each of the unicast IBFLY networks 402A, 402B may be different than one another. Thus, each of the unicast IBFLY networks 402A, 402B reads a respective set of data samples from the data memory 401 having a predetermined data sample length (such as 16 data samples, 32 data samples, etc.) in accordance with the width of the data path associated with the interconnections between the unicast IBFLY networks 402A, 402B and the data memory 401, as well as the width of the data paths between the unicast IBFLY networks 402A, 402B and the multicast BFLY networks 404A, 404B, 404C, 404D. The time-aligned data samples output via each of the unicast IBFLY networks 402A, 402B represent portions of a larger set of data samples (such as a data block of a predetermined sample size) that are subjected to processing operations to eventually generate the output data samples that are stored back in the data memory 401 once output by the Benes network 408, as discussed in further detail below.

The time-aligned data samples output by the unicast IBFLY networks 402A, 402B may differ from one another in terms of representing different portions of a larger set of data samples, which may be based upon the architecture of the programmable processing array and the number data samples in the data sets that are processed by the functional blocks. To provide an illustrative and non-limiting scenario, the particular time window of data samples stored in the data memory 401, which are to be subjected to filter processing operations, may be of a length M (i.e. contain data samples 0 through M), which is greater than the size of the data samples contained in the data sample sets (such as vectors) that are processed via the multicast butterfly networks 404A, 404B, 404C, 404D each processing operation. Thus, the data sets (or vectors) may comprise 32 data samples by way of a non-limiting and illustrative scenario, such that the unicast IBFLY networks 402A, 404B receive time-aligned data samples corresponding to one portion of the M data samples, and the unicast IBFLY networks 402C, 402D receive time-aligned data samples corresponding to another, different portion of the M data samples. The different portions of the M data samples that are time-aligned and output by each of the unicast IBFLY networks 402A, 402B in this manner may differ from one another based upon the filter type and accompanying filter processing operations that are to be performed.

Thus, “time-aligned” in this context means in a temporal or time-wise order, but not necessarily starting with the first data sample in the larger set of data samples that are subjected to processing operations. Instead, the time-aligned data samples output by each of the unicast IBFLY networks 402A, 402B are output in accordance with a sliding time window pattern that is based upon a type of filter processing operation that is to be performed on the data samples read from the data memory 401. Thus, the first data sample within the data sets output by each of the unicast IBFLY networks 402A, 402B may differ from one another in terms of one, two, four data samples, etc., based upon the filter type and accompanying filter processing operations that are to be performed. Again, once the data sets are time-aligned via each of the unicast IBFLY networks 402A, 402B, these data sets are then output to each respectively-coupled multicast butterfly network 404A, 404B, 404C, 404D as shown in FIG. 4.

Each of the multicast butterfly networks 402A, 402B, 402C, and 402D is configured to perform processing operations on the time-aligned data samples received via the unicast IBFLY networks 402A, 402B as noted above to generate respective data sets (such as vectors) of any suitable length. As noted above for the unicast IBFLY networks 402A, 402B, a multicast butterfly network is also specific implementation of a butterfly network, which is a form of a multistage interconnection network topology used to connect different nodes in a multiprocessor system. However, a multicast butterfly network is configured to provide multiple outputs from a single input. Therefore, in the non-limiting and illustrative scenario used herein, the data vectors are 32 data samples in length, and thus each of the multicast butterfly networks 402A, 402B, 402C, and 402D is configured to output two different sets of 32 data samples, or two vectors each, per clock cycle. Each clock cycle may include the execution by each of the multicast butterfly networks 404A, 404B, 404C, and 404D of processing operations in accordance with a received processor instruction, as noted above.

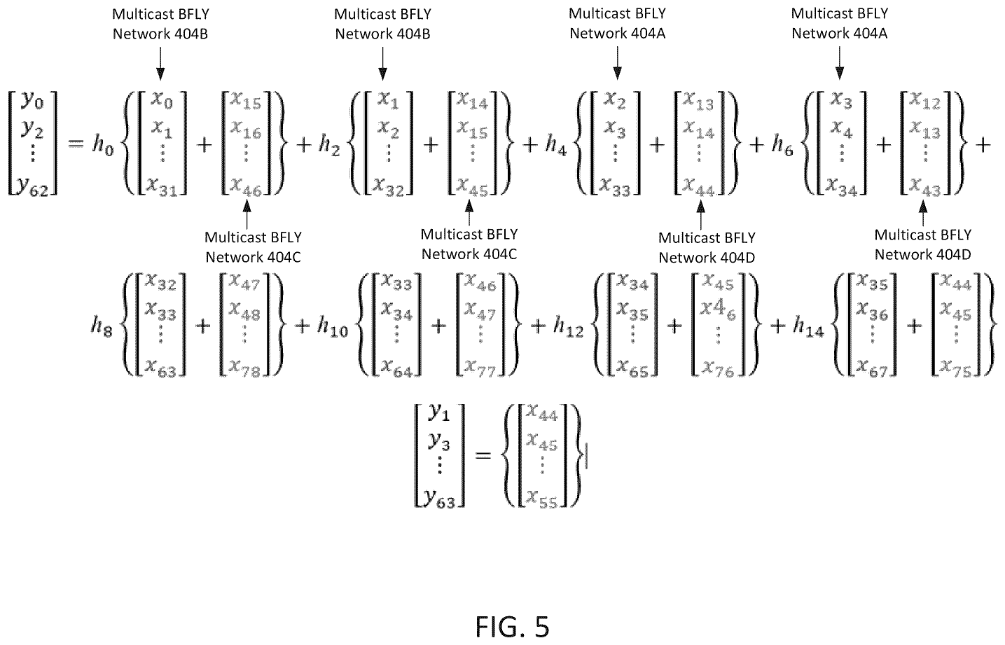

Because of the architecture of the multicast butterfly networks 402A, 402B, 402C, and 402D, the processed sets of data samples output via the multicast butterfly networks 402A, 402B, 402C, and 402D are generated in accordance with a sliding time window pattern based upon a type of filter processing operation that is to be performed on the data samples read from the data memory 401. This is clarified by way of reference to FIG. 5, which illustrates a non-limiting and illustrative use of filter processing operations for the implementation of a vectorized half band interpolation filter with 31 taps, and a central tap of 1. Each set of data samples in this scenario is a vector having a size of 32 elements (i.e. 32 data samples).

Thus, the vectorized filter operation as shown in FIG. 5 is the result each of the of the multicast butterfly networks 402A, 402B, 402C, and 402D performing a specific type of filter processing operation on the data-samples that are read from the data memory 401, which are time-aligned and output by the unicast IBFLY networks 402A, 402B as noted above. With continued reference to FIG. 5, it is shown that the multicast BFLY network 404A outputs two sets of processed data samples, i.e. two vectors, each having a length or size of 32 data samples. In other words, each of these processed sets of data samples [x₂ . . . x₃₃] and [x₃ . . . x₃₄] as shown in FIG. 5 is the result of the multicast BFLY network 404A performing processing operations on data samples received via the unicast IBFLY network 402A. Likewise, the multicast BFLY network 404B outputs two sets of processed data samples, i.e. two vectors, each having a length or size of 32 data samples each. Each of these processed sets of data samples [x₀ . . . x₃₁] and [x₁ . . . x₃₂] as shown in FIG. 5 is also the result of the multicast BFLY network 404B performing processing operations on data samples received via the unicast IBFLY network 402A.

This is also the case for each of the multicast butterfly networks 402C, 404D. That is, the multicast BFLY networks 404C, 404D output two sets, respectively, of processed data samples, i.e. two vectors, each having a length or size of 32 data samples. However, although the multicast BFLY networks 404A, 404B receive the same sets of time-aligned data samples via the same unicast BFLY network 402A, the processed data samples output by each of the multicast butterfly networks 404A, 404B differ from one another in terms of their starting data sample position, or index. Likewise, although the multicast BFLY networks 404C, 404D receive the same sets of time-aligned data samples via the same unicast BFLY network 402B, the processed data samples output by each of the multicast butterfly networks 404C, 404D also differ from one another in terms of their starting data sample position, or index.

That is, for the scenario as shown in FIG. 5, filter processing operations are implemented in accordance with a vectorized half band interpolation filter having 31 taps, and a central tap of 1. Thus, the multicast IBFLY networks 404A, 404B, 404C, 404D generate their respective output vectors in accordance with a sliding time window pattern that is dependent upon the particular filter processing operations that are being performed. In the case of a half band interpolation filter processing operations as illustrated in FIG. 5, each output vector is offset from one another by one, as shown by the starting x data sample position in each of the vectors in the top row. However, for other filter processing operations, this index or offset may differ such that other sliding time window patterns are realized. The sliding time window patterns are thus known a priori and established by way of the processing instructions sent to the multicast IBFLY networks 404A, 404B, 404C, 404D.

For the scenario as shown in FIG. 5, the first row of data sample sets includes a total of 8 vectors, two output via each of the multicast IBFLY networks 404A, 404B. Thus, the top row of 8 output vectors represents the output for a single clock cycle, during which time each of the multicast IBFLY networks 404A, 404B, 404C, 404D generates a respective output vector based upon the executed filter processing operations that are performed on the time-aligned data samples as noted above. This scenario is provided in a non-limiting and illustrative manner, and is one scenario based upon the length of the vectors being 32 samples each. The programmable processing array 400 may support data lanes configured to support larger or smaller sets of data samples per clock cycle, and the filter processing operations may require additional clock cycles depending upon the number of taps and/or the type of filter that is to be realized.

In any event, after one or more clock cycles, a number of vectors output via the multicast IBFLY networks 404A, 404B, 404C, 404D are transferred to each of the multiplication and adder units 406A, 406B. For the scenario as shown in FIG. 5, four vectors are transferred to each of the multiplication and adder units 406A, 406B after a single clock cycle. These vectors correspond to those shown in the first row of FIG. 5, i.e. the vectors corresponding to the filter coefficients h0, h2, h4, and h6. On the next clock cycle, the next eight vectors are output via the multicast IBFLY networks 404A, 404B, 404C, 404D, which correspond to the middle row as shown in FIG. 5, i.e. the vectors corresponding to the filter coefficients h8, h10, h12, and h14. This process may continue over any suitable number of clock cycles in this way until each of the vectors to be output in accordance with the particular filter processing operations are completed and transferred to the multiplication and adder units 406A, 406B.

Thus, the interconnections between the multicast IBFLY networks 404A, 404B, 404C, 404D and each respectively-coupled multiplication and adder unit 406A, 406B may represent a set of predetermined wired interconnections that enable loading of sets of processed data samples generated by the multicast IBFLY networks 404A, 404B, 404C, 404D (such as vectors) of a predetermined size from each of the multicast IBFLY networks 404A, 404B, 404C, 404D to each multiplication and adder unit 406A, 406B as part of a respective data lane.

Each of the multiplication and adder unit 406A, 406B thus represents functional blocks that are configured to perform predetermined computations on the sets of data samples received in this manner. In this case, the predetermined computations represent the summation of sets of data samples output by the multicast IBFLY networks 404A, 404B, 404C, 404D, as well as a multiplication of these summed sets of data samples by respective filter coefficients. Thus, the multiplication and adder unit 406A, 406B may represent dedicated hardware configured for this purpose, which may be implemented via the execution units 304.1-304.N as noted above, and may facilitate data lanes of any suitable width to enable these computations for vectors of any suitable size.

Continuing the scenario as shown in FIG. 5, the multiplication and adder unit 406A is thus configured to sum the vectors received via the multicast IBFLY networks 404B and 404C. Therefore, the multiplication and adder unit 406A is configured to receive a total of four sets of data samples (i.e. vectors), two from the multicast IBFLY network 404B, and two from the multicast IBFLY network 404C. The multiplication and adder unit 406A is configured to sum each of these sets of data samples as shown in FIG. 5 to provide a set of summed data samples, i.e. a set of summed vectors. That is, and with continued reference to the scenario as shown in FIG. 5, the multiplication and adder unit 406A is configured to sum the processed sets of data samples [x₀ . . . x₃₁] with the processed sets of data samples [x₁₅ . . . x₄₆] to provide a first summed vector, and to sum the processed sets of data samples [x₁ . . . x₃₂] with the processed sets of data samples [x₁₄ . . . x₄₅] to provide a second summed vector.

Furthermore, the multiplication and adder unit 406A is configured to perform a vector multiplication of each one of the first and second summed vectors by a respective filter coefficient h₀ and h₂, as shown in FIG. 5. These filter coefficients may be known a priori based upon the particular type of filter that is to be realized via the execution of the filter processing operations, as noted herein. Thus, filter coefficients h in this case may correspond to those of a half-band interpolation filter, and the number of such filter coefficients may be selected based upon the particular filter type as well as the number of data samples that are to be processed via the programmable processing array 400.

To implement the multiplication of the summed vectors by their respective filter coefficients in this way, the programmable processing array 400 may comprise a coefficient lookup table (LUT) 450, as shown in FIG. 5. The filter coefficient LUT 450 may be implemented in hardware (e.g., dedicated hardwired circuits or memory), firmware, software, or any combination thereof. The filter coefficient LUT 450 is configured to store any suitable number of filter coefficients corresponding to each one of the filter types for each of the various filter processing operations that the programmable processing array 400 is configured to perform on the data samples retrieved from the data memory 401, as discussed herein. Thus, the processor instructions may contain information regarding the particular set of filter coefficients that are to be used based upon the type of filter, the number of data samples in each set, the data path width, etc.

Therefore, each one of the multiplication and adder units 406A, 406B is configured to obtain the required filter coefficients to perform the multiplication operations based upon the set of filter coefficients stored in the coefficient LUT 450. To do so, the programmable processing array 400 may further comprise a coefficient clone logic 460, which is coupled to the coefficient LUT 450 and to each one of the multiplication and adder units 406A, 406B. The coefficient clone logic 460 may be implemented in hardware, firmware, software, or any combination thereof. In a non-limiting and illustrative scenario, the coefficient clone logic 460 may be implemented as a multiplexer network, which may clone (i.e. copy) any suitable number of filter coefficients stored in the filter coefficient LUT 450, which are then provided to the multiplication and adder units 406A, 406B. Thus, the coefficient clone logic 460 may be coupled to the filter coefficient LUT 450 and to each one of the multiplication and adder units 406A, 406B via a set of predetermined wired interconnections, which enable loading of sets of data samples identified with the cloned and/or stored filter coefficients of a predetermined size from the filter coefficients LUT 450 to the multiplication and adder units 406A, 406B.

Thus, the number of filter coefficients that may be cloned is a function of the data path width as well as the number of filter operations to be performed in a single clock cycle. Using the present scenario as discussed with reference to FIGS. 4 and 5, the coefficient clone logic 460 is configured to clone up to four filter coefficients stored in the coefficient LUT 450, which may be provided to the multiplication and adder units 406A, 406B as discussed herein. The coefficient clone logic 460 may advantageously clone the filter coefficients in this way to exploit the often symmetric nature of filter coefficients. That is, for a half-band interpolation filter, the coefficients h₀, h₂, h₄, and h₅ may be identical to the filter coefficients h₈, h₁₀, h₁₂, and h₁₄. The programmable processing array 400 may thus copy the identical filter coefficient data to the other data paths utilized by the multicast networks 404A, 404B, 404C, 404D when applicable to increase the efficiency of the overall processing operations.

In any event, the multiplication and adder unit 406A is configured to perform a multiplication processing operation to multiply each summed vector by its respective filter coefficient. With reference to the scenario as shown in FIG. 5, the multiplication and adder unit 406A is configured to multiply the first summed vector (i.e. the processed sets of data samples [x₀ . . . x₃₁] summed with the processed sets of data samples [x₁₅ . . . x₄₆]) by the filter coefficient h₀, and to multiply the second summed vector (i.e. the processed sets of data samples [x₁ . . . x₃₂] summed with the processed sets of data samples [x₁₄ . . . x₄₅]) by the filter coefficient h₂.

It is noted that the filter coefficient properties may be leveraged in accordance with the redundancy of filter coefficients for a particular filter type that is implemented in conjunction with the distributive property of mathematics to condense the summing and multiplication steps for each coefficient into a single operation. Thus, for a half-band interpolation filter, there are additional filter coefficients that are typically multiplied separately by the set of data samples output by the multicast butterfly networks 404C, 404D. That is, a filter coefficient h₃₁ may be multiplied by the vector [x₁₅ . . . x₄₆]. However, for a half-band interpolation filter, the filter coefficients are symmetrical in that the last filter coefficient h₃₁ is equal to the first filter coefficient h₀, with increasing and decreasing filter coefficients also being identical to one another in a symmetric fashion.

Therefore, the programmable processing array 400 may implement a symmetric architecture that comprises a “main” data path comprising the data flow identified with the unicast inverse butterfly network 402A and the multicast butterfly networks 404A, 404B. The programmable processing array 400 may also implement a “symmetric” data path comprising the data flow identified with the unicast inverse butterfly network 402B and the multicast butterfly networks 404C, 404D. Although not every filter type may have symmetric filter coefficients that allow for this property to be exploited, the programmable processing array 400 utilizes these main and symmetric data paths such that the processing operations for such symmetric filter types may be efficiently performed.

That is, and with reference to FIG. 5, the symmetric properties of the half-band interpolation filter coefficients allow for the multiplication of the processed sets of data samples [x₀ . . . x₃₁] and [x₁₅ . . . x₄₆] by the same filter coefficient h₀, as these two filter coefficients are identical to one another. In this way, the programmable processing array 400 intelligently performs filter processing operations based upon the parameters of the filter type for which the filter processing operations are to be performed on the data samples retrieved from the data memory 401. Again, such operations may be identified beforehand based upon each filter type, such that the processor instructions results in the execution of filter processing operations to realize an efficient computation of output data for each filter type, leveraging the architecture of the programmable processing array 400 in each case.

Likewise, the multiplication and adder unit 406B is configured to perform the same summing and multiplication processing operations as the multiplication and adder unit 406A, but with respect to the processed data samples received via the multicast BFLY networks 404A, 404D. Thus, and with continued reference to FIG. 5, the multiplication and adder unit 406B is configured to sum the processed sets of data samples [x₂ . . . x₃₃] and the processed sets of data samples [x₁₃ . . . x₄₄]), which are multiplied by the filter coefficient h₄, and to sum the processed sets of data samples [x₃ . . . x₃₄] and the processed sets of data samples [x₁₂ . . . x₄₃]), which are multiplied by the filter coefficient h₆.

In this way, the first row of multiplication and summation operations are performed via the multiplication and adder units 406A, 406B in a single clock cycle. As shown and discussed with reference to FIG. 5 each of the multiplication and adder units 406A, 406B is configured to perform processing operations on four sets of data samples (i.e. four vectors). However, alternate configurations are possible, in which additional or fewer sets of data samples are processed each clock cycle. For instance, it is noted that for the half-band interpolation filter operations as shown in FIG. 5, the filter coefficients are real, and thus each of the multiplication and adder using 406A, 406B may perform addition and multiplication for two coefficients simultaneously. That is, the multiplication and adder unit 406A computes the output data samples identified with filter coefficients h₀ and h₂, while the multiplication and adder unit 406B computes the output data samples identified with filter coefficients h₄ and h₆. In other words, the multiplication and adder units 406A, 406B perform semi-complex operations. For other filter types that utilize complex filter coefficients, additional clock cycles may be required.

These processing operations are then repeated for a subsequent clock cycle, resulting in the middle row of processing operations being performed as shown in FIG. 5, in a similar manner via each of the multiplication and adder units 406A, 406B. Thus, and as shown in FIG. 5, after two clock cycles a set of even output data samples [y₀ . . . y₆₂] are generated, which represent the result of a specific set of filter processing operations being performed on the data samples x read from the data memory 401 in accordance with a filter type corresponding to a half-band interpolation filter. For a half-band interpolation filter, the odd output data samples [y₁ . . . y₆₃] are simply equal to a time-shifted set of data samples read from the data memory 401. Of course, for other filter types, the odd output data samples calculated in this manner may require additional clock cycles and processing operations to be performed via the multiplication and adder units 406A, 406B.

In any event, the output set of data samples, i.e. the output data vector, comprises a set of even and odd output samples [y₀ . . . y₆₃], which represents the result of the half-band interpolating filter processing operations being executed on a block of the data samples x read from the data memory 401. To generate the output data vector in a format that is then stored back in the data memory 401, the programmable processing array 400 comprises an output interface (also referred to herein as an output formatter) configured to generate the output data vector, which again is based upon the data vectors output via each multicast butterfly network 404A, 404B, 404C, 404D. In this way, the output data vector represents the result of the filter operations that are performed via the programmable processing array architecture 400 on the block of data samples x read from the data memory 401 in accordance with the specific filter type.

The output interface thus functions to combine, or interleave, the even and odd sets of output data vectors to produce a single set of data samples as the output vector. The output interface may thus be implemented as any suitable type of network, hardware, software, or combinations of these to facilitate the generation of the output vector in this manner. The output interface 408 may be implemented as any suitable type of post-processing formatting network that functions to compact the output data into a natural format, which is then stored back in the data memory 401. In a non-limiting and illustrative scenario as shown in FIG. 4, the output interface comprises a Benes network 408, which is a specialized type of a Clos network having more than three stages. Thus, the output interface may be implemented as any suitable structure and architecture, including known types thereof, and may be configured as a rearrangeable nonblocking network configured to combine any suitable type of data sets output via each multicast butterfly network 404A, 404B, 404C, 404D over subsequent clock cycles, which may include the even and odd computations as noted above.

Thus, the output vector y represents a set of any suitable number N of data samples, which correspond to filter processing operations that are performed on any suitable number N of data samples x read from the data memory 401 in accordance with a selected filter type. Thus, the data samples x and the output data samples y may have a filter transfer function relationship with respect to one another in accordance with the type of filter and associated filter processing operations that are performed via the programmable processing array 400. For the scenario as described with respect to FIG. 5, the output vector is thus generated in three clock cycles for a block of 64 data samples read from the data memory 401. This process may be repeated any suitable number of times to process any suitable number of data blocks in this manner, with the output vector in each case being stored back in the data memory 401 such that the output data samples may be accessed in accordance with the desired application. Thus, the interconnections between the output interface (such as the Benes network 408) and the data memory 401 may represent a set of predetermined wired interconnections that enable loading of sets of output data samples a predetermined size into the data memory 401.

Again, the filter processing operations may be performed in accordance with one of several different filter types based upon the particular processing instructions that are provided in accordance with the desired application. Thus, to provide a non-limiting and illustrative scenario, the programmable processing array 400 is configured to perform any suitable number of different filter processing operations, or any other suitable type of operations, based upon the processing instructions that are provided to the functional blocks of the programmable processing array 400. This allows flexibility of the programmable processing array 400 with respect to providing a large range of vectorized filter processing operations within a single platform and for a variety of applications. The programmable processing array 400 may be flexibly controlled to realize any suitable number and/or type of processing operations, which again may include those identified with DFE functions, filter processing operations, or any other suitable type of processing operations. The unicast inverse butterfly networks 402A. 402B, the multicast butterfly networks 404A, 404B, 404C, 404D, and the output interface (such as the Benes network 408) may be realized via any suitable type of control bit generation scheme. In a non-limiting and illustrative scenario, this may include the generation of control bits in accordance with a residue partitioning algorithm, which may utilize the processor instructions as discussed herein.

In the case of filter processing operations, a non-limiting and illustrative Table 1 is provided below, which indicates the input data sample format (i.e. the x data samples read from the data memory 401 and time-aligned), the filter coefficient format, and the output data sample y format (i.e. the output data output via the Benes network 408), for a number of different corresponding FIR filter types. These FIR filter types are not intended to be exhaustive or limiting, and are provided to demonstrate the flexibility of the programmable processing array 400 to accommodate different types of FIR filter processing operations as noted herein.

TABLE 1

| Data Sample | Coefficient | Output sample | |
|---|---|---|---|
| Format | Format | Format | FIR Filter Type |
| 32 bit complex | 16 bit real | 32 bit complex | Non-symmetric |
| 32 bit complex | 16 bit real | 32 bit complex | Symmetric |
| 32 bit complex | 16 bit real | 32 bit complex | Anti-symmetric |
| 32 bit complex | 16 bit real | 32 bit complex | HB Interpolation |
| 32 bit complex | 16 bit real | 32 bit complex | HB Decimation |
| 32 bit complex | 32 bit complex | 32 bit complex | Non-symmetric |
| 32 bit complex | 32 bit complex | 64 bit complex | Non-symmetric |
| 64 bit complex | 16 bit real | 64 bit complex | Symmetric |
| 64 bit complex | 16 bit real | 64 bit complex | HB Decimation |
| 64 bit complex | 32 bit complex | 64 bit complex | Non-symmetric |
| 64 bit complex | 16 bit real | 64 bit complex | Non-Symmetric |
| 32 bit complex | 16 bit real | 32 bit complex | Fractional 3/1 |
| | | | Interpolation |
| 64 bit complex | 16 bit real | 64 bit complex | Fraction ⅓ |
| | | | Decimation |
| 32 bit complex | 16 bit real | 32 bit complex | Fractional 4/3 |
| | | | Interpolation |
| 64 bit complex | 16 bit real | 64 bit complex | Fractional ¾ |
| | | | Decimation |

### Device Implementing a Vector Processor Architecture

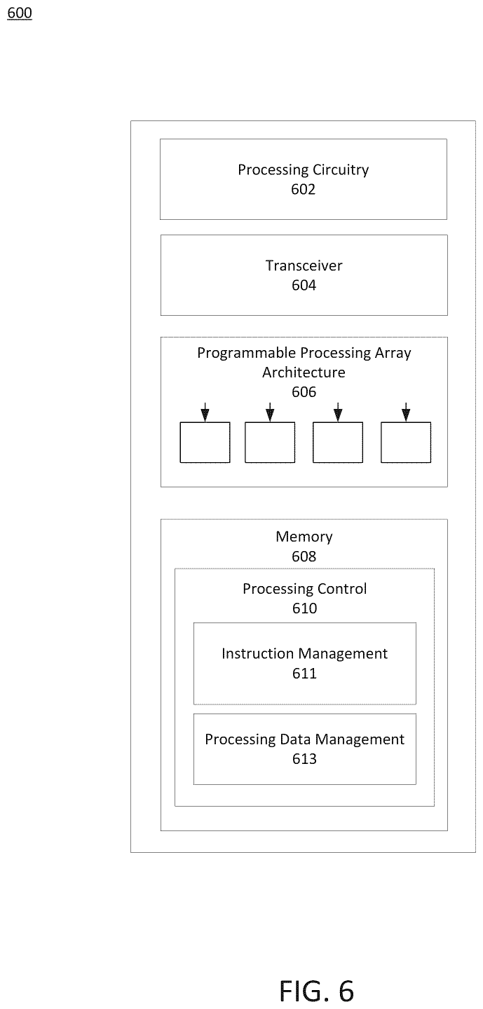

FIG. 6 illustrates an example device, in accordance with the present disclosure. The device 600 may be identified with one or more devices implementing a programmable processing array architecture to perform processing operations, such as the programmable processor architectures 300, 400 as shown and discussed herein with reference to FIGS. 3 and 4. The device 600 may be identified with a wireless device, a user equipment (UE) or other suitable device configured to perform wireless communications such as a mobile phone, a laptop computer, a cellular base station, a tablet, etc., which may include one or more components configured to transmit and receive radio signals, and to use processing operations as discussed herein to perform digital signal processing in accordance with wirelessly transmitted and/or received data, which may include filter processing, DFE processing, etc., as discussed herein. Alternatively, the device 600 may be identified with a graphics processing unit (GPU), which may perform graphic processing on streams of graphical data.

As further discussed below, the device 600 may perform the functions as discussed herein with respect to the programmable processing array architecture 300, 400 as shown and discussed herein with reference to FIGS. 3 and 4. The device 600 may perform processing operations by receiving processor instructions having any suitable number of fields. These processing operations may be performed using locally-implemented or embedded buffers to store sets of data samples and the output of performing data processing on the stored sets of data samples. To do so, the device 600 may include processing circuitry 602, a transceiver 604, a programmable processing array architecture 606, and a memory 608. The components shown in FIG. 6 are provided for case of explanation, and the device 600 may implement additional, less, or alternative components as those shown in FIG. 6. In one scenario, the transceiver 604 may be omitted when the device 600 is implemented as a GPU.

The processing circuitry 602 may be configured as any suitable number and/or type of computer processors, which may function to control the device 600 and/or other components of the device 600. The processing circuitry 602 may be identified with one or more processors (or suitable portions thereof) implemented by the device 600. The processing circuitry 602 may be identified with one or more processors such as a host processor, a digital signal processor, one or more microprocessors, graphics processors, baseband processors, microcontrollers, an application-specific integrated circuit (ASIC), part (or the entirety of) a field-programmable gate array (FPGA), etc.

In any event, the processing circuitry 602 may be configured to carry out instructions to perform arithmetical, logical, and/or input/output (I/O) operations, and/or to control the operation of one or more components of device 600 to perform various functions as described herein. The processing circuitry 602 may include one or more microprocessor cores, memory registers, buffers, clocks, etc., and may generate electronic control signals associated with the components of the device 600 to control and/or modify the operation of these components. The processing circuitry 602 may communicate with and/or control functions associated with the transceiver 604, the programmable processing array architecture 606, and/or the memory 608.

The transceiver 604 (when present) may be implemented as any suitable number and/or type of components configured to transmit and/or receive data (such as data packets) and/or wireless signals in accordance with any suitable number and/or type of communication protocols. The transceiver 604 may include any suitable type of components to facilitate this functionality, including components associated with known transceiver, transmitter, and/or receiver operation, configurations, and implementations. Although depicted in FIG. 6 as a transceiver, the transceiver 604 may include any suitable number of transmitters, receivers, or combinations of these that may be integrated into a single transceiver or as multiple transceivers or transceiver modules. The transceiver 604 may include components typically identified with an RF front end and include antennas, ports, power amplifiers (PAS), RF filters, mixers, local oscillators (LOs), low noise amplifiers (LNAs), upconverters, downconverters, channel tuners, etc. Thus, the transceiver 604 may be configured as any suitable number and/or type of components configured to facilitate receiving and/or transmitting data and/or signals in accordance with one or more communication protocols. The transceiver 604 may be implemented as any suitable number and/or type of components to support wireless communications such as analog-to-digital converters (ADCs), digital to analog converters, intermediate frequency (IF) amplifiers and/or filters, modulators, demodulators, baseband processors, etc. The data received via the transceiver 604 (e.g. wireless signal data streams), data provided to the transceiver 604 for transmission (e.g. data streams for transmission), and/or data used in conjunction with the transmission and/or reception of data via the transceiver 604 (e.g. digital filter coefficients, DPD terms, etc.) may be processed as data streams via the programmable processing array architecture 606, as discussed herein. Thus, the programmable processing array architecture 606 may be identified with the programmable processing array architecture 300, 400 as shown and described herein with reference to FIGS. 3 and 4.

The memory 608 is configured to store data and/or instructions such that, when the instructions are executed by the processing circuitry 602, cause the device 600 to perform various functions as described herein with respect to the programmable processing array architecture 606, such as controlling, monitoring, and/or regulating the flow of data through the programmable processing array architecture 606. The memory 608 may be implemented as any suitable volatile and/or non-volatile memory, including read-only memory (ROM), random access memory (RAM), flash memory, a magnetic storage media, an optical disc, erasable programmable read only memory (EPROM), programmable read only memory (PROM), etc. The memory 608 may be non-removable, removable, or a combination of both. The memory 608 may be implemented as a non-transitory computer readable medium storing one or more executable instructions such as, for example, logic, algorithms, code, etc.

As further discussed below, the instructions, logic, code, etc., stored in the memory 608 are represented by the various modules as shown, which may enable the functionality disclosed herein to be functionally realized. Alternatively, the modules as shown in FIG. 6 that are associated with the memory 608 may include instructions and/or code to facilitate control and/or monitor the operation of hardware components implemented via the device 600. In other words, the modules shown in FIG. 6 are provided for ease of explanation regarding the functional association between hardware and software components. Thus, the processing circuitry 602 may execute the instructions stored in these respective modules in conjunction with one or more hardware components to perform the various functions as discussed herein.

The processing control engine 610 may represent the functionality described herein as discussed with reference to controlling and/or monitoring the programmable processing array architecture 606. The processing control engine 610 may represent the program memory 306 (and stored instruction sets), the decoder 320, and/or the vector data memory 301 as discussed herein with reference to FIG. 3. Additionally or alternatively, one or more of the program memory 306, the decoder 320, and/or the vector data memory 301 may form part of the processing circuitry 602, the memory 608, or separate components not shown in FIG. 6.

The executable instructions stored in the instruction management module 611 may facilitate, in conjunction with execution via the processing circuitry 602, the device 600 receiving and decoding processor instructions (which may be sent via the processing circuitry 602 or other suitable component of the device 600 or a component external to the device 600), and providing data blocks of samples to the programmable processing array architecture 606 (e.g. from the data memory 401 or suitable data source as discussed herein). This may include a determination of each specific processor instruction to perform specific types of processing operations and/or any of the functionality as discussed herein with respect to the programmable processing array architecture 400 such as reading data samples from and writing data samples to the data memory 401, the generation of processor instructions and/or control bits, writing data samples to the local buffers 308.1-308.N, reading data samples from the local buffers 308.1-308.N, the calculations identified with various processing operations executed via the unicast inverse butterfly networks 402A, 402B, the multicast butterfly networks 404A, 404B, 404C, 404D, the multiplication and adder units 406A, 408B, the output interface (such as the Benes network 408), etc.

The executable instructions stored in the processing data management module 613 may facilitate, in conjunction with execution via the processing circuitry 602, the determination of when the calculated results of processing operations are completed and the output data samples stored in the data memory 401. This may include writing the results in one or more vector registers 302.1-302.N and/or sending the vector data sample results to the data memory 401 and/or the I/O data to be utilized by the appropriate components of the device 600 or other suitable device.

### General Operation of a First SoC

A system on a chip (SoC) is provided, which may be with reference to an SoC implementing the programmable processing array architecture 300 as shown in FIG. 3. The SoC comprises a memory configured to store data samples and vector processing circuitry. The vector processing circuitry comprises a first set of multicast butterfly networks, with an input of each one of the first set of multicast butterfly networks being coupled to an output of a first unicast inverse butterfly network. The vector processing circuitry also comprises a second set of multicast butterfly networks, with an input of each one of the second set of multicast butterfly networks being coupled to an output of a second unicast inverse butterfly network. Each multicast butterfly network from among the first and the second set of multicast butterfly networks is configured to perform, on data samples output via a respectively coupled one of the first and the second unicast inverse butterfly networks, processing operations to generate respective data vectors comprising processed data samples. The SoC further comprises an output interface configured to generate an output data vector based upon the data vectors output via each multicast butterfly network from among the first and the second set of multicast butterfly networks, the output vector representing a result of filter processing operations that are performed on data samples read from the memory in accordance with a selected filter type. Furthermore, each one of the first unicast inverse butterfly network and the second unicast inverse butterfly network is configured to respectively de-rotate data samples read from the memory to output, to each respectively coupled multicast butterfly network from among the first and the second set of multicast butterfly networks, vectors comprising time-aligned data samples. In addition or in alternative to and in any combination with the optional features previously explained in this paragraph, each multicast butterfly network from among the first and the second set of multicast butterfly networks is configured to generate respective data vectors comprising processed data samples in accordance with a sliding time window pattern based upon the selected filter type. In addition or in alternative to and in any combination with the optional features previously explained in this paragraph, the output interface comprises a Benes network. In addition or in alternative to and in any combination with the optional features previously explained in this paragraph, the filter type is from among a plurality of filter types, and the vector processing circuitry is configured to perform filter processing operations on data samples read from the memory in accordance with a set of processing instructions based upon the selected filter type. In addition or in alternative to and in any combination with the optional features previously explained in this paragraph, the selected filter type is selected from among a set of selectable filter types comprising: a non-symmetric filter; a symmetric filter; an anti-symmetric filter; a half-band interpolation filter; a half-band decimation filter; a fractional 3/1 interpolation filter; a fractional ⅓ decimation filter; a fractional 4/3 interpolation filter; and a fractional ¾ interpolation filter. In addition or in alternative to and in any combination with the optional features previously explained in this paragraph, the first set of multicast butterfly networks comprises a first and a second multicast butterfly network, the first multicast butterfly network being configured to output, by performing processing operations on data samples received via the first unicast inverse butterfly network, a first set of vectors, and the second multicast butterfly network being configured to output, by performing processing operations on data samples received via the first unicast inverse butterfly network, a second set of vectors. In addition or in alternative to and in any combination with the optional features previously explained in this paragraph, the second set of multicast butterfly networks comprises a third and a fourth multicast butterfly network, the third multicast butterfly network being configured to output, by performing processing operations on data samples received via the second unicast inverse butterfly network, a third set of vectors, and the fourth multicast butterfly network being configured to output, by performing processing operations on data samples received via the second unicast inverse butterfly network, a fourth set of vectors. In addition or in alternative to and in any combination with the optional features previously explained in this paragraph, the vector processing circuitry further comprises: a first multiplication and adder unit configured to sum respective ones of the second set of vectors with respective ones of the third set of vectors to provide a first set of summed vectors; and a second multiplication and adder unit configured to sum respective ones of the first set of vectors with respective ones of the fourth set of vectors to provide a second set of summed vectors. In addition or in alternative to and in any combination with the optional features previously explained in this paragraph, the first multiplication and adder unit is configured to multiply each one of the first set of summed vectors by a respective filter coefficient, and the second multiplication and adder unit is configured to multiply each one of the second set of summed vectors by a respective filter coefficient. In addition or in alternative to and in any combination with the optional features previously explained in this paragraph, the filter type is from among a plurality of filter types, and further comprising: a filter coefficient lookup table (LUT) configured to store filter coefficients corresponding to each one of the plurality of filter types, and each one of the first multiplication and adder unit and the second multiplication and adder unit is configured to obtain the filter coefficients that are multiplied by each of the first and the second set of summed vectors, respectively, based upon the set of filter coefficients stored in the LUT. In addition or in alternative to and in any combination with the optional features previously explained in this paragraph, the SoC further comprises coefficient clone logic configured to generate a copy of the filter coefficients retrieved from the coefficient LUT to provide sets of identical coefficient vectors corresponding to the same filter coefficients.

### General Operation of a Second SoC

Another system on a chip (SoC) is provided, which may be with reference to an SoC implementing the programmable processing array architecture 300 as shown in FIG. 3. The SoC comprises a memory configured to store data samples and a programmable processing array. The programmable processing array comprises a first set of multicast butterfly networks, with an input of each one of the first set of multicast butterfly networks being coupled to an output of a first unicast inverse butterfly network, and a second set of multicast butterfly networks, with an input of each one of the second set of multicast butterfly networks being coupled to an output of a second unicast inverse butterfly network. Each multicast butterfly network from among the first and the second set of multicast butterfly networks is configured to perform, on data samples output via a respectively coupled one of the first and the second unicast inverse butterfly networks, processing operations to generate respective sets of processed data samples. The SoC further comprises an output interface configured to generate an output set of data samples based upon the processed data samples output via each multicast butterfly network from among the first and the second set of multicast butterfly networks, the output set of data samples representing a result of digital front end (DFE) processing operations that are performed on data samples read from the memory in accordance with a selected DFE function. Furthermore, each one of the first unicast inverse butterfly network and the second unicast inverse butterfly network is configured to respectively de-rotate data samples read from the memory to output, to each respectively coupled multicast butterfly network from among the first and the second set of multicast butterfly networks, sets of time-aligned data samples. In addition or in alternative to and in any combination with the optional features previously explained in this paragraph, each multicast butterfly network from among the first and the second set of multicast butterfly networks is configured to generate respective sets of processed data samples in accordance with a sliding time window pattern based upon the selected DFE function. In addition or in alternative to and in any combination with the optional features previously explained in this paragraph, the output interface comprises a Benes network. In addition or in alternative to and in any combination with the optional features previously explained in this paragraph, the DFE processing operations comprise filter processing operations in accordance with a selected filter type from among a plurality of filter types, and the programmable processing array is configured to perform filter processing operations on data samples read from the memory in accordance with a set of processing instructions based upon the selected filter type. In addition or in alternative to and in any combination with the optional features previously explained in this paragraph, the selected filter is selected from among a set of selectable filter types comprising: a non-symmetric filter; a symmetric filter; an anti-symmetric filter; a half-band interpolation filter; a half-band decimation filter; a fractional 3/1 interpolation filter; a fractional ⅓ decimation filter; a fractional 4/3 interpolation filter; and a fractional ¾ interpolation filter. In addition or in alternative to and in any combination with the optional features previously explained in this paragraph, the first set of multicast butterfly networks comprises a first and a second multicast butterfly network, the first multicast butterfly network being configured to output, by performing processing operations on data samples received via the first unicast inverse butterfly network, a first set of processed data samples, and the second multicast butterfly network being configured to output, by performing processing operations on data samples received via the first unicast inverse butterfly network, a second set of processed data samples. In addition or in alternative to and in any combination with the optional features previously explained in this paragraph, the second set of multicast butterfly networks comprises a third and a fourth multicast butterfly network, the third multicast butterfly network being configured to output, by performing processing operations on data samples received via the second unicast inverse butterfly network, a third set of processed data samples, and the fourth multicast butterfly network being configured to output, by performing processing operations on data samples received via the second unicast inverse butterfly network, a fourth set of processed data samples. In addition or in alternative to and in any combination with the optional features previously explained in this paragraph, the programmable processing array further comprises: a first multiplication and adder unit configured to sum respective ones of the second set of processed data samples with respective ones of the third set of processed data samples to provide a first set of summed processed data samples; and a second multiplication and adder unit configured to sum respective ones of the first set of processed data samples with respective ones of the fourth set of processed data samples to provide a second set of summed processed data samples. In addition or in alternative to and in any combination with the optional features previously explained in this paragraph, the first multiplication and adder unit is configured to multiply each one of the first set of summed processed data samples by a respective filter coefficient, and the second multiplication and adder unit is configured to multiply each one of the second set of summed processed data samples by a respective filter coefficient. In addition or in alternative to and in any combination with the optional features previously explained in this paragraph, the DFE processing operations comprise filter processing operations in accordance with a selected filter type from among a plurality of filter types, and further comprising: a filter coefficient lookup table (LUT) configured to store filter coefficients corresponding to each one of the plurality of filter types, each of the first multiplication and adder unit and the second multiplication and adder unit is configured to obtain the filter coefficients that are multiplied by each of the first and the second set of summed processed data samples, respectively, based upon the set of filter coefficients stored in the LUT. In addition or in alternative to and in any combination with the optional features previously explained in this paragraph, the SoC further comprises a coefficient clone logic configured to generate a copy of the filter coefficients retrieved from the coefficient LUT to provide sets of identical coefficient data samples corresponding to the same filter coefficients.

### Process Flow

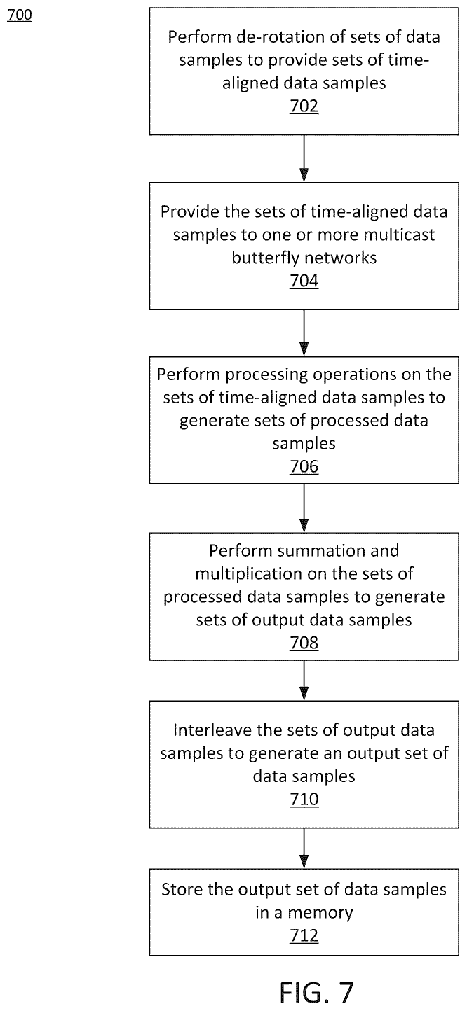

FIG. 7 illustrates a process flow. With reference to FIG. 7, the process flow 700 may be a computer-implemented method executed by and/or otherwise associated with one or more processors (processing circuitry) and/or storage devices. These processors and/or storage devices may be associated with one or more components of the programmable processing array architecture 300, 400 as discussed herein and/or one or more components of the device 600 as discussed herein. The processors and/or storage devices may be identified with the one or more execution units 304.1-304.N, processor circuitry 310.1-310.N executing vector processor instructions, and or the programmable processing array architecture 606, as discussed above. The flow 700 may include alternate or additional steps that are not shown in FIG. 7 for purposes of brevity, and may be performed in a different order than the steps shown in FIG. 7.

Flow 700 may begin when one or more processors perform (block 702) de-rotation of sets of data samples to provide sets of time-aligned data samples. This de-rotation may be performed, in one non-limiting and illustrative scenario, via the unicast inverse butterfly networks 402A, 402B with respect to the sets of data samples retrieved form the data memory 401, as discussed herein.

Flow 700 may include one or more processors providing (block 704) the sets of time-aligned data samples to one or more multicast butterfly networks. This may include, in one non-limiting and illustrative scenario, the unicast inverse butterfly networks 402A, 402B providing the time-aligned sets of data samples to the multicast butterfly networks 404A, 404B, 404C, 404D, as noted herein.

Flow 700 may include one or more processors performing (block 706) processing operations on time-aligned data samples to generate sets of processed data samples. This may include, in one non-limiting and illustrative scenario, the execution of DFE processing operations such as filter processing operations, which may include the generation of sets of data samples in accordance with a time-sliding window pattern in accordance with the particular instructions that are provided to the multicast butterfly networks 404A, 404B, 404C, 404D, as noted herein.

Flow 700 may include one or more processors performing (block 708) summation and multiplication on the sets of processed data samples to generate sets of output data samples. This may include, in one non-limiting and illustrative scenario, the summation of the vectors output via the multicast butterfly networks 404A, 404B, 404C, 404D, and the multiplication of summed vectors via the filter coefficients h, as discussed herein. This summation and multiplication may be executed via the multiplication and adder units 406A, 406B.

Flow 700 may include one or more processors interleaving (block 710) the sets of output data samples to generate an output set of data samples. This may include, in one non-limiting and illustrative scenario, the interleaving of the even and odd output data samples generated via the multiplication and adder units 406A, 406B, as discussed herein. This interleaving process may be executed via the Benes network 408 or other suitable output interface that performs post-processing.

Flow 700 may include one or more processors storing (block 712) the output set of data samples in a memory. This may include, in one non-limiting and illustrative scenario, the output of the Benes network 408 or other suitable output interface being stored in the data memory 401, as discussed herein.

### Examples

The following examples pertain to various techniques of the present disclosure.

An example (e.g. example 1) is directed to a system on a chip (SoC), comprising: a memory configured to store data samples; and vector processing circuitry, comprising: a first set of multicast butterfly networks, an input of each one of the first set of multicast butterfly networks being coupled to an output of a first unicast inverse butterfly network; a second set of multicast butterfly networks, an input of each one of the second set of multicast butterfly networks being coupled to an output of a second unicast inverse butterfly network, wherein each multicast butterfly network from among the first and the second set of multicast butterfly networks is configured to perform, on data samples output via a respectively coupled one of the first and the second unicast inverse butterfly networks, processing operations to generate respective data vectors comprising processed data samples; and an output interface configured to generate an output data vector based upon the data vectors output via each multicast butterfly network from among the first and the second set of multicast butterfly networks, the output vector representing a result of filter processing operations that are performed on data samples read from the memory in accordance with a selected filter type.

Another example (e.g. example 2) relates to a previously-described example (e.g. example 1), wherein each one of the first unicast inverse butterfly network and the second unicast inverse butterfly network is configured to respectively de-rotate data samples read from the memory to output, to each respectively coupled multicast butterfly network from among the first and the second set of multicast butterfly networks, vectors comprising time-aligned data samples.

Another example (e.g. example 3) relates to a previously-described example (e.g. one or more of examples 1-2), wherein each multicast butterfly network from among the first and the second set of multicast butterfly networks is configured to generate respective data vectors comprising processed data samples in accordance with a sliding time window pattern based upon the selected filter type.

Another example (e.g. example 4) relates to a previously-described example (e.g. one or more of examples 1-3), wherein the output interface comprises a Benes network.

Another example (e.g. example 5) relates to a previously-described example (e.g. one or more of examples 1-4), wherein the filter type is from among a plurality of filter types, and wherein the vector processing circuitry is configured to perform filter processing operations on data samples read from the memory in accordance with a set of processing instructions based upon the selected filter type.

Another example (e.g. example 6) relates to a previously-described example (e.g. one or more of examples 1-5), wherein the selected filter type is selected from among a set of selectable filter types comprising: a non-symmetric filter; a symmetric filter; an anti-symmetric filter; a half-band interpolation filter; a half-band decimation filter; a fractional 3/1 interpolation filter; a fractional ⅓ decimation filter; a fractional 4/3 interpolation filter; and a fractional ¾ interpolation filter.

Another example (e.g. example 7) relates to a previously-described example (e.g. one or more of examples 1-6), wherein the first set of multicast butterfly networks comprises a first and a second multicast butterfly network, the first multicast butterfly network being configured to output, by performing processing operations on data samples received via the first unicast inverse butterfly network, a first set of vectors, and the second multicast butterfly network being configured to output, by performing processing operations on data samples received via the first unicast inverse butterfly network, a second set of vectors.

Another example (e.g. example 8) relates to a previously-described example (e.g. one or more of examples 1-7), wherein the second set of multicast butterfly networks comprises a third and a fourth multicast butterfly network, the third multicast butterfly network being configured to output, by performing processing operations on data samples received via the second unicast inverse butterfly network, a third set of vectors, and the fourth multicast butterfly network being configured to output, by performing processing operations on data samples received via the second unicast inverse butterfly network, a fourth set of vectors.

Another example (e.g. example 9) relates to a previously-described example (e.g. one or more of examples 1-8), wherein the vector processing circuitry further comprises: a first multiplication and adder unit configured to sum respective ones of the second set of vectors with respective ones of the third set of vectors to provide a first set of summed vectors; and a second multiplication and adder unit configured to sum respective ones of the first set of vectors with respective ones of the fourth set of vectors to provide a second set of summed vectors.

Another example (e.g. example 10) relates to a previously-described example (e.g. one or more of examples 1-9), wherein the first multiplication and adder unit is configured to multiply each one of the first set of summed vectors by a respective filter coefficient, and wherein the second multiplication and adder unit is configured to multiply each one of the second set of summed vectors by a respective filter coefficient.

Another example (e.g. example 11) relates to a previously-described example (e.g. one or more of examples 1-10), wherein the filter type is from among a plurality of filter types, and further comprising: a filter coefficient lookup table (LUT) configured to store filter coefficients corresponding to each one of the plurality of filter types, and wherein each one of the first multiplication and adder unit and the second multiplication and adder unit is configured to obtain the filter coefficients that are multiplied by each of the first and the second set of summed vectors, respectively, based upon the set of filter coefficients stored in the LUT.

Another example (e.g. example 12) relates to a previously-described example (e.g. one or more of examples 1-11), further comprising: coefficient clone logic configured to generate a copy of the filter coefficients retrieved from the coefficient LUT to provide sets of identical coefficient vectors corresponding to the same filter coefficients.

An example (e.g. example 13) is directed to a system on a chip (SoC), comprising: a memory configured to store data samples; and a programmable processing array, comprising: a first set of multicast butterfly networks, an input of each one of the first set of multicast butterfly networks being coupled to an output of a first unicast inverse butterfly network; a second set of multicast butterfly networks, an input of each one of the second set of multicast butterfly networks being coupled to an output of a second unicast inverse butterfly network, wherein each multicast butterfly network from among the first and the second set of multicast butterfly networks is configured to perform, on data samples output via a respectively coupled one of the first and the second unicast inverse butterfly networks, processing operations to generate respective sets of processed data samples; and an output interface configured to generate an output set of data samples based upon the processed data samples output via each multicast butterfly network from among the first and the second set of multicast butterfly networks, the output set of data samples representing a result of digital front end (DFE) processing operations that are performed on data samples read from the memory in accordance with a selected DFE function.

Another example (e.g. example 14) relates to a previously-described example (e.g. example 13), wherein each one of the first unicast inverse butterfly network and the second unicast inverse butterfly network is configured to respectively de-rotate data samples read from the memory to output, to each respectively coupled multicast butterfly network from among the first and the second set of multicast butterfly networks, sets of time-aligned data samples.

Another example (e.g. example 15) relates to a previously-described example (e.g. one or more of examples 13-14), wherein each multicast butterfly network from among the first and the second set of multicast butterfly networks is configured to generate respective sets of processed data samples in accordance with a sliding time window pattern based upon the selected DFE function.

Another example (e.g. example 16) relates to a previously-described example (e.g. one or more of examples 13-15), wherein the output interface comprises a Benes network.

Another example (e.g. example 17) relates to a previously-described example (e.g. one or more of examples 13-16), wherein the DFE processing operations comprise filter processing operations in accordance with a selected filter type from among a plurality of filter types, and wherein the programmable processing array is configured to perform filter processing operations on data samples read from the memory in accordance with a set of processing instructions based upon the selected filter type.

Another example (e.g. example 18) relates to a previously-described example (e.g. one or more of examples 13-17), wherein the selected filter is selected from among a set of selectable filter types comprising: a non-symmetric filter; a symmetric filter; an anti-symmetric filter; a half-band interpolation filter; a half-band decimation filter; a fractional 3/1 interpolation filter; a fractional ⅓ decimation filter; a fractional 4/3 interpolation filter; and a fractional ¾ interpolation filter.

Another example (e.g. example 19) relates to a previously-described example (e.g. one or more of examples 13-18), wherein the first set of multicast butterfly networks comprises a first and a second multicast butterfly network, the first multicast butterfly network being configured to output, by performing processing operations on data samples received via the first unicast inverse butterfly network, a first set of processed data samples, and the second multicast butterfly network being configured to output, by performing processing operations on data samples received via the first unicast inverse butterfly network, a second set of processed data samples.

Another example (e.g. example 20) relates to a previously-described example (e.g. one or more of examples 13-19), wherein the second set of multicast butterfly networks comprises a third and a fourth multicast butterfly network, the third multicast butterfly network being configured to output, by performing processing operations on data samples received via the second unicast inverse butterfly network, a third set of processed data samples, and the fourth multicast butterfly network being configured to output, by performing processing operations on data samples received via the second unicast inverse butterfly network, a fourth set of processed data samples.

Another example (e.g. example 21) relates to a previously-described example (e.g. one or more of examples 13-20), wherein the programmable processing array further comprises: a first multiplication and adder unit configured to sum respective ones of the second set of processed data samples with respective ones of the third set of processed data samples to provide a first set of summed processed data samples; and a second multiplication and adder unit configured to sum respective ones of the first set of processed data samples with respective ones of the fourth set of processed data samples to provide a second set of summed processed data samples.

Another example (e.g. example 22) relates to a previously-described example (e.g. one or more of examples 13-21), wherein the first multiplication and adder unit is configured to multiply each one of the first set of summed processed data samples by a respective filter coefficient, and wherein the second multiplication and adder unit is configured to multiply each one of the second set of summed processed data samples by a respective filter coefficient.

Another example (e.g. example 23) relates to a previously-described example (e.g. one or more of examples 13-22), wherein the DFE processing operations comprise filter processing operations in accordance with a selected filter type from among a plurality of filter types, and further comprising: a filter coefficient lookup table (LUT) configured to store filter coefficients corresponding to each one of the plurality of filter types, and wherein each of the first multiplication and adder unit and the second multiplication and adder unit is configured to obtain the filter coefficients that are multiplied by each of the first and the second set of summed processed data samples, respectively, based upon the set of filter coefficients stored in the LUT.

Another example (e.g. example 24) relates to a previously-described example (e.g. one or more of examples 13-23), further comprising: coefficient clone logic configured to generate a copy of the filter coefficients retrieved from the coefficient LUT to provide sets of identical coefficient data samples corresponding to the same filter coefficients.

An example (e.g. example 25) is directed to a system on a chip (SoC), comprising: a storage means for storing data samples; and a vector processing means, comprising: a first set of multicast butterfly networks, an input of each one of the first set of multicast butterfly networks being coupled to an output of a first unicast inverse butterfly network; a second set of multicast butterfly networks, an input of each one of the second set of multicast butterfly networks being coupled to an output of a second unicast inverse butterfly network, wherein each multicast butterfly network from among the first and the second set of multicast butterfly networks is configured to perform, on data samples output via a respectively coupled one of the first and the second unicast inverse butterfly networks, processing operations to generate respective data vectors comprising processed data samples; and an output interface means for generating an output data vector based upon the data vectors output via each multicast butterfly network from among the first and the second set of multicast butterfly networks, the output vector representing a result of filter processing operations that are performed on data samples read from the storage means in accordance with a selected filter type.

Another example (e.g. example 26) relates to a previously-described example (e.g. example 25), wherein each one of the first unicast inverse butterfly network and the second unicast inverse butterfly network is configured to respectively de-rotate data samples read from the storage means to output, to each respectively coupled multicast butterfly network from among the first and the second set of multicast butterfly networks, vectors comprising time-aligned data samples.

Another example (e.g. example 27) relates to a previously-described example (e.g. one or more of examples 25-26), wherein each multicast butterfly network from among the first and the second set of multicast butterfly networks is configured to generate respective data vectors comprising processed data samples in accordance with a sliding time window pattern based upon the selected filter type.

Another example (e.g. example 28) relates to a previously-described example (e.g. one or more of examples 25-27), wherein the output interface means comprises a Benes network.

Another example (e.g. example 29) relates to a previously-described example (e.g. one or more of examples 25-28), wherein the filter type is from among a plurality of filter types, and wherein the vector processing means is configured to perform filter processing operations on data samples read from the storage means in accordance with a set of processing instructions based upon the selected filter type.

Another example (e.g. example 30) relates to a previously-described example (e.g. one or more of examples 25-29), wherein the selected filter type is selected from among a set of selectable filter types comprising: a non-symmetric filter; a symmetric filter; an anti-symmetric filter; a half-band interpolation filter; a half-band decimation filter; a fractional 3/1 interpolation filter; a fractional ⅓ decimation filter; a fractional 4/3 interpolation filter; and a fractional ¾ interpolation filter.

Another example (e.g. example 31) relates to a previously-described example (e.g. one or more of examples 25-30), wherein the first set of multicast butterfly networks comprises a first and a second multicast butterfly network, the first multicast butterfly network being configured to output, by performing processing operations on data samples received via the first unicast inverse butterfly network, a first set of vectors, and the second multicast butterfly network being configured to output, by performing processing operations on data samples received via the first unicast inverse butterfly network, a second set of vectors.

Another example (e.g. example 32) relates to a previously-described example (e.g. one or more of examples 25-31), wherein the second set of multicast butterfly networks comprises a third and a fourth multicast butterfly network, the third multicast butterfly network being configured to output, by performing processing operations on data samples received via the second unicast inverse butterfly network, a third set of vectors, and the fourth multicast butterfly network being configured to output, by performing processing operations on data samples received via the second unicast inverse butterfly network, a fourth set of vectors.

Another example (e.g. example 33) relates to a previously-described example (e.g. one or more of examples 25-32), wherein the vector processing means further comprises: a first multiplication and adder unit configured to sum respective ones of the second set of vectors with respective ones of the third set of vectors to provide a first set of summed vectors; and a second multiplication and adder unit configured to sum respective ones of the first set of vectors with respective ones of the fourth set of vectors to provide a second set of summed vectors.

Another example (e.g. example 34) relates to a previously-described example (e.g. one or more of examples 25-33), wherein the first multiplication and adder unit is configured to multiply each one of the first set of summed vectors by a respective filter coefficient, and wherein the second multiplication and adder unit is configured to multiply each one of the second set of summed vectors by a respective filter coefficient.

Another example (e.g. example 35) relates to a previously-described example (e.g. one or more of examples 25-34), wherein the filter type is from among a plurality of filter types, and further comprising: a filter coefficient lookup table (LUT) configured to store filter coefficients corresponding to each one of the plurality of filter types, and wherein each one of the first multiplication and adder unit and the second multiplication and adder unit is configured to obtain the filter coefficients that are multiplied by each of the first and the second set of summed vectors, respectively, based upon the set of filter coefficients stored in the LUT.

Another example (e.g. example 36) relates to a previously-described example (e.g. one or more of examples 25-35), further comprising: coefficient cloning means for generating a copy of the filter coefficients retrieved from the coefficient LUT to provide sets of identical coefficient vectors corresponding to the same filter coefficients.

An example (e.g. example 37) is directed to a system on a chip (SoC), comprising: a storage means for storing data samples; and a programmable processing array means, comprising: a first set of multicast butterfly networks, an input of each one of the first set of multicast butterfly networks being coupled to an output of a first unicast inverse butterfly network; a second set of multicast butterfly networks, an input of each one of the second set of multicast butterfly networks being coupled to an output of a second unicast inverse butterfly network, wherein each multicast butterfly network from among the first and the second set of multicast butterfly networks is configured to perform, on data samples output via a respectively coupled one of the first and the second unicast inverse butterfly networks, processing operations to generate respective sets of processed data samples; and an output interface means for generating an output set of data samples based upon the processed data samples output via each multicast butterfly network from among the first and the second set of multicast butterfly networks, the output set of data samples representing a result of digital front end (DFE) processing operations that are performed on data samples read from the storage means in accordance with a selected DFE function.

Another example (e.g. example 38) relates to a previously-described example (e.g. example 37), wherein each one of the first unicast inverse butterfly network and the second unicast inverse butterfly network is configured to respectively de-rotate data samples read from the storage means to output, to each respectively coupled multicast butterfly network from among the first and the second set of multicast butterfly networks, sets of time-aligned data samples.

Another example (e.g. example 39) relates to a previously-described example (e.g. one or more of examples 37-38), wherein each multicast butterfly network from among the first and the second set of multicast butterfly networks is configured to generate respective sets of processed data samples in accordance with a sliding time window pattern based upon the selected DFE function.

Another example (e.g. example 40) relates to a previously-described example (e.g. one or more of examples 37-39), wherein the output interface means comprises a Benes network.

Another example (e.g. example 41) relates to a previously-described example (e.g. one or more of examples 37-40), wherein the DFE processing operations comprise filter processing operations in accordance with a selected filter type from among a plurality of filter types, and wherein the programmable processing array means performs filter processing operations on data samples read from the storage means in accordance with a set of processing instructions based upon the selected filter type.

Another example (e.g. example 42) relates to a previously-described example (e.g. one or more of examples 37-41), wherein the selected filter is selected from among a set of selectable filter types comprising: a non-symmetric filter; a symmetric filter; an anti-symmetric filter; a half-band interpolation filter; a half-band decimation filter; a fractional 3/1 interpolation filter; a fractional ⅓ decimation filter; a fractional 4/3 interpolation filter; and a fractional ¾ interpolation filter.

Another example (e.g. example 43) relates to a previously-described example (e.g. one or more of examples 37-42), wherein the first set of multicast butterfly networks comprises a first and a second multicast butterfly network, the first multicast butterfly network being configured to output, by performing processing operations on data samples received via the first unicast inverse butterfly network, a first set of processed data samples, and the second multicast butterfly network being configured to output, by performing processing operations on data samples received via the first unicast inverse butterfly network, a second set of processed data samples.

Another example (e.g. example 44) relates to a previously-described example (e.g. one or more of examples 37-43), wherein the second set of multicast butterfly networks comprises a third and a fourth multicast butterfly network, the third multicast butterfly network being configured to output, by performing processing operations on data samples received via the second unicast inverse butterfly network, a third set of processed data samples, and the fourth multicast butterfly network being configured to output, by performing processing operations on data samples received via the second unicast inverse butterfly network, a fourth set of processed data samples.

Another example (e.g. example 45) relates to a previously-described example (e.g. one or more of examples 37-44), wherein the programmable processing array means further comprises: a first multiplication and adder unit configured to sum respective ones of the second set of processed data samples with respective ones of the third set of processed data samples to provide a first set of summed processed data samples; and a second multiplication and adder unit configured to sum respective ones of the first set of processed data samples with respective ones of the fourth set of processed data samples to provide a second set of summed processed data samples.

Another example (e.g. example 46) relates to a previously-described example (e.g. one or more of examples 37-45), wherein the first multiplication and adder unit is configured to multiply each one of the first set of summed processed data samples by a respective filter coefficient, and wherein the second multiplication and adder unit is configured to multiply each one of the second set of summed processed data samples by a respective filter coefficient.

Another example (e.g. example 47) relates to a previously-described example (e.g. one or more of examples 37-46), wherein the DFE processing operations comprise filter processing operations in accordance with a selected filter type from among a plurality of filter types, and further comprising: a filter coefficient lookup table (LUT) configured to store filter coefficients corresponding to each one of the plurality of filter types, and wherein each of the first multiplication and adder unit and the second multiplication and adder unit is configured to obtain the filter coefficients that are multiplied by each of the first and the second set of summed processed data samples, respectively, based upon the set of filter coefficients stored in the LUT.

Another example (e.g. example 48) relates to a previously-described example (e.g. one or more of examples 37-47), further comprising: a coefficient cloning means for generating a copy of the filter coefficients retrieved from the coefficient LUT to provide sets of identical coefficient data samples corresponding to the same filter coefficients.

An apparatus as shown and described.

A method as shown and described.

### CONCLUSION

The aforementioned description will so fully reveal the general nature of the disclosure that others can, by applying knowledge within the skill of the art, readily modify and/or adapt for various applications without undue experimentation, and without departing from the general concept of the present disclosure. Therefore, such adaptations and modifications are intended to be within the meaning and range of equivalents of the disclosed implementations, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

References in the specification to “one implementation,” “an implementation,” “an exemplary implementation,” etc., indicate that the implementation described may include a particular feature, structure, or characteristic, but every implementation may not necessarily include the particular feature, structure, or characteristic. Moreover, such phrases are not necessarily referring to the same implementation. Further, when a particular feature, structure, or characteristic is described in connection with an implementation, it is submitted that it is within the knowledge of one skilled in the art to affect such feature, structure, or characteristic in connection with other implementations whether or not explicitly described.

The implementation described herein are provided for illustrative purposes, and are not limiting. Other implementation are possible, and modifications may be made to the described implementations. Therefore, the specification is not meant to limit the disclosure. Rather, the scope of the disclosure is defined only in accordance with the following claims and their equivalents.

The implementations described herein may be facilitated in hardware (e.g., circuits), firmware, software, or any combination thereof. Implementations may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact results from computing devices, processors, controllers, or other devices executing the firmware, software, routines, instructions, etc. Further, any of the implementation variations may be carried out by a general purpose computer.

For the purposes of this discussion, the term “processing circuitry” or “processor circuitry” shall be understood to be circuit(s), processor(s), logic, or a combination thereof. For example, a circuit can include an analog circuit, a digital circuit, state machine logic, other structural electronic hardware, or a combination thereof. A processor can include a microprocessor, a digital signal processor (DSP), or other hardware processor. The processor can be “hard-coded” with instructions to perform corresponding function(s) according to implementations described herein. Alternatively, the processor can access an internal and/or external memory to retrieve instructions stored in the memory, which when executed by the processor, perform the corresponding function(s) associated with the processor, and/or one or more functions and/or operations related to the operation of a component having the processor included therein.

In one or more of the implementations described herein, processing circuitry can include memory that stores data and/or instructions. The memory can be any well-known volatile and/or non-volatile memory, including, for example, read-only memory (ROM), random access memory (RAM), flash memory, a magnetic storage media, an optical disc, erasable programmable read only memory (EPROM), and programmable read only memory (PROM). The memory can be non-removable, removable, or a combination of both.

What is claimed is:

1. A system on a chip (SoC), comprising:
a memory configured to store data samples; and
vector processing circuitry, comprising:
a first set of multicast butterfly networks, an input of each one of the first set of multicast butterfly networks being coupled to an output of a first unicast inverse butterfly network;
a second set of multicast butterfly networks, an input of each one of the second set of multicast butterfly networks being coupled to an output of a second unicast inverse butterfly network,
wherein each multicast butterfly network from among the first and the second set of multicast butterfly networks is configured to perform, on data samples output via a respectively coupled one of the first and the second unicast inverse butterfly networks, processing operations to generate respective data vectors comprising processed data samples; and
an output interface configured to generate an output data vector based upon the data vectors output via each multicast butterfly network from among the first and the second set of multicast butterfly networks, the output vector representing a result of filter processing operations that are performed on data samples read from the memory in accordance with a selected filter type.

2. The SoC of claim 1, wherein each one of the first unicast inverse butterfly network and the second unicast inverse butterfly network is configured to respectively de-rotate data samples read from the memory to output, to each respectively coupled multicast butterfly network from among the first and the second set of multicast butterfly networks, vectors comprising time-aligned data samples.

3. The SoC of claim 1, wherein each multicast butterfly network from among the first and the second set of multicast butterfly networks is configured to generate respective data vectors comprising processed data samples in accordance with a sliding time window pattern based upon the selected filter type.

4. The SoC of claim 1, wherein the output interface comprises a Benes network.

5. The SoC of claim 1, wherein the filter type is from among a plurality of filter types, and
wherein the vector processing circuitry is configured to perform filter processing operations on data samples read from the memory in accordance with a set of processing instructions based upon the selected filter type.

6. The SoC of claim 5, wherein the selected filter type is selected from among a set of selectable filter types comprising:
a non-symmetric filter;
a symmetric filter;
an anti-symmetric filter;
a half-band interpolation filter;
a half-band decimation filter;
a fractional 3/1 interpolation filter;
a fractional ⅓ decimation filter;
a fractional 4/3 interpolation filter; and
a fractional ¾ interpolation filter.

7. The SoC of claim 1, wherein the first set of multicast butterfly networks comprises a first and a second multicast butterfly network, the first multicast butterfly network being configured to output, by performing processing operations on data samples received via the first unicast inverse butterfly network, a first set of vectors, and the second multicast butterfly network being configured to output, by performing processing operations on data samples received via the first unicast inverse butterfly network, a second set of vectors.

8. The SoC of claim 7, wherein the second set of multicast butterfly networks comprises a third and a fourth multicast butterfly network, the third multicast butterfly network being configured to output, by performing processing operations on data samples received via the second unicast inverse butterfly network, a third set of vectors, and the fourth multicast butterfly network being configured to output, by performing processing operations on data samples received via the second unicast inverse butterfly network, a fourth set of vectors.

9. The SoC of claim 8, wherein the vector processing circuitry further comprises:
a first multiplication and adder unit configured to sum respective ones of the second set of vectors with respective ones of the third set of vectors to provide a first set of summed vectors; and
a second multiplication and adder unit configured to sum respective ones of the first set of vectors with respective ones of the fourth set of vectors to provide a second set of summed vectors.

10. The SoC of claim 9, wherein the first multiplication and adder unit is configured to multiply each one of the first set of summed vectors by a respective filter coefficient, and
wherein the second multiplication and adder unit is configured to multiply each one of the second set of summed vectors by a respective filter coefficient.

11. The SoC of claim 10, wherein the filter type is from among a plurality of filter types, and further comprising:
a filter coefficient lookup table (LUT) configured to store filter coefficients corresponding to each one of the plurality of filter types, and
wherein each one of the first multiplication and adder unit and the second multiplication and adder unit is configured to obtain the filter coefficients that are multiplied by each of the first and the second set of summed vectors, respectively, based upon the set of filter coefficients stored in the LUT.

12. The SoC of claim 11, further comprising:
coefficient clone logic configured to generate a copy of the filter coefficients retrieved from the coefficient LUT to provide sets of identical coefficient vectors corresponding to the same filter coefficients.

13. A system on a chip (SoC), comprising:
a memory configured to store data samples; and
a programmable processing array, comprising:
a first set of multicast butterfly networks, an input of each one of the first set of multicast butterfly networks being coupled to an output of a first unicast inverse butterfly network;
a second set of multicast butterfly networks, an input of each one of the second set of multicast butterfly networks being coupled to an output of a second unicast inverse butterfly network,
wherein each multicast butterfly network from among the first and the second set of multicast butterfly networks is configured to perform, on data samples output via a respectively coupled one of the first and the second unicast inverse butterfly networks, processing operations to generate respective sets of processed data samples; and
an output interface configured to generate an output set of data samples based upon the processed data samples output via each multicast butterfly network from among the first and the second set of multicast butterfly networks, the output set of data samples representing a result of digital front end (DFE) processing operations that are performed on data samples read from the memory in accordance with a selected DFE function.

14. The SoC of claim 13, wherein each one of the first unicast inverse butterfly network and the second unicast inverse butterfly network is configured to respectively de-rotate data samples read from the memory to output, to each respectively coupled multicast butterfly network from among the first and the second set of multicast butterfly networks, sets of time-aligned data samples.

15. The SoC of claim 13, wherein each multicast butterfly network from among the first and the second set of multicast butterfly networks is configured to generate respective sets of processed data samples in accordance with a sliding time window pattern based upon the selected DFE function.

16. The SoC of claim 13, wherein the output interface comprises a Benes network.

17. The SoC of claim 13, wherein the DFE processing operations comprise filter processing operations in accordance with a selected filter type from among a plurality of filter types, and
wherein the programmable processing array is configured to perform filter processing operations on data samples read from the memory in accordance with a set of processing instructions based upon the selected filter type.

18. The SoC of claim 17, wherein the selected filter is selected from among a set of selectable filter types comprising:
a non-symmetric filter;
a symmetric filter;
an anti-symmetric filter;
a half-band interpolation filter;
a half-band decimation filter;
a fractional 3/1 interpolation filter;
a fractional ⅓ decimation filter;
a fractional 4/3 interpolation filter; and
a fractional ¾ interpolation filter.

19. The SoC of claim 13, wherein the first set of multicast butterfly networks comprises a first and a second multicast butterfly network, the first multicast butterfly network being configured to output, by performing processing operations on data samples received via the first unicast inverse butterfly network, a first set of processed data samples, and the second multicast butterfly network being configured to output, by performing processing operations on data samples received via the first unicast inverse butterfly network, a second set of processed data samples.

20. The SoC of claim 19, wherein the second set of multicast butterfly networks comprises a third and a fourth multicast butterfly network, the third multicast butterfly network being configured to output, by performing processing operations on data samples received via the second unicast inverse butterfly network, a third set of processed data samples, and the fourth multicast butterfly network being configured to output, by performing processing operations on data samples received via the second unicast inverse butterfly network, a fourth set of processed data samples.

21. The SoC of claim 20, wherein the programmable processing array further comprises:
a first multiplication and adder unit configured to sum respective ones of the second set of processed data samples with respective ones of the third set of processed data samples to provide a first set of summed processed data samples; and
a second multiplication and adder unit configured to sum respective ones of the first set of processed data samples with respective ones of the fourth set of processed data samples to provide a second set of summed processed data samples.

22. The SoC of claim 21, wherein the first multiplication and adder unit is configured to multiply each one of the first set of summed processed data samples by a respective filter coefficient, and
wherein the second multiplication and adder unit is configured to multiply each one of the second set of summed processed data samples by a respective filter coefficient.

23. The SoC of claim 21, wherein the DFE processing operations comprise filter processing operations in accordance with a selected filter type from among a plurality of filter types, and further comprising:
a filter coefficient lookup table (LUT) configured to store filter coefficients corresponding to each one of the plurality of filter types, and
wherein each of the first multiplication and adder unit and the second multiplication and adder unit is configured to obtain the filter coefficients that are multiplied by each of the first and the second set of summed processed data samples, respectively, based upon the set of filter coefficients stored in the LUT.

24. The SoC of claim 23, further comprising:
coefficient clone logic configured to generate a copy of the filter coefficients retrieved from the coefficient LUT to provide sets of identical coefficient data samples corresponding to the same filter coefficients.
